(19) United States
(12) Patent Application Publication
(10) Pub. No.: US 2024/0243106 A1
(43) Pub. Date: Jul. 18, 2024

(54) Thermal Enhanced Power Semiconductor Package

(71) Applicant: Wolfspeed, Inc., Durham, NC (US)

(72) Inventors: Daniel Ginn Richter, Raleigh, NC (US); Yusheng Lin, Phoenix, AZ (US)

(21) Appl. No.: 18/456,782

(22) Filed: Aug. 28, 2023

Related U.S. Application Data
(63) Continuation-in-part of application No. 18/154,353, filed on Jan. 13, 2023.

(51) Int. Cl. H01L 25/07; H01L 23/00; H01L 23/367; H01L 23/495; H01L 29/16

(52) U.S. Cl. CPC H01L 25/072; H01L 23/367; H01L 23/49537; H01L 23/49575; H01L 24/08; H01L 24/32; H01L 24/97; H01L 29/1608; H01L 2224/08238; H01L 2224/08258; H01L 2224/32225; H01L 2224/32245; H01L 2224/97; H01L 2924/12032; H01L 2924/13091

(57) ABSTRACT

Semiconductor packages are provided. In one example, a power semiconductor package includes a first carrier submount, a second carrier submount, and a plurality of semiconductor die. Each semiconductor die of the plurality of semiconductor die has a first surface and an opposing second surface. Furthermore, for each semiconductor die of the plurality of semiconductor die, the first surface is directly coupled to the first carrier submount, and the second surface is directly coupled to the second carrier submount.

### PRIORITY CLAIM

This application is a continuation-in-part of and claims priority to U.S. patent application Ser. No. 18/154,353, having a filing date of Jan. 13, 2023, which is incorporated by reference in its entirety herein.

### FIELD

The present disclosure relates generally to semiconductor packages.

### BACKGROUND

Semiconductor devices such as transistors and diodes are ubiquitous in modem electronic devices. Wide band gap semiconductor material systems such as gallium arsenide (GaAs), gallium nitride (GaN), and silicon carbide (SiC) are being increasingly utilized in semiconductor devices to push the boundaries of device performance in areas such as switching speed, power handling capability, and thermal conductivity. Example power semiconductor devices may include metal-oxide-semiconductor field-effect transistors (MOSFETs), insulated gate bipolar transistors (IGBTs), Schottky barrier diodes, PiN diodes, thyristors, and high electron mobility transistors (HEMTs). Packaging technology may play a large role in the performance of power semiconductor devices.

### SUMMARY

Aspects and advantages of embodiments of the present disclosure will be set forth in part in the following description, or may be learned from the description, or may be learned through practice of the embodiments.

One example embodiment of the present disclosure is directed to a power semiconductor package. The power semiconductor package includes a first carrier submount, a second carrier submount, and a plurality of semiconductor die. Each semiconductor die of the plurality of semiconductor die has a first surface and an opposing second surface. Furthermore, for each semiconductor die of the plurality of semiconductor die, the first surface is directly coupled to the first carrier submount, and the second surface is directly coupled to the second carrier submount.

Another example embodiment of the present disclosure is directed to a power semiconductor package. The power semiconductor package includes a first carrier submount, a second carrier submount, and a plurality of semiconductor die. The first carrier submount has a first conductive layer and a second conductive layer. Each semiconductor die of the plurality of semiconductor die includes a first surface and an opposing second surface, a source contact and a gate contact on the first surface, and a drain contact on the second surface. Furthermore, for each semiconductor die of the plurality of semiconductor die, the first surface is directly coupled to the first carrier submount such that the source contact is directly coupled to the first conductive layer of the first carrier submount and the gate contact is directly coupled to the second conductive layer of the first carrier submount. Even further, for each semiconductor die of the plurality of semiconductor die, the second surface is directly coupled to the second carrier submount.

Another example embodiment of the present disclosure is directed to a power semiconductor package. The power semiconductor package includes a carrier submount comprising one or more conductive patterns, a first lead frame comprising one or more conductive leads, a second lead frame comprising one or more conductive leads, a first semiconductor die having a first surface directly coupled to the carrier submount and an opposing second surface directly coupled to the first lead frame, and a second semiconductor die having a first surface directly coupled to the carrier submount and an opposing second surface directly coupled to the second lead frame. The first semiconductor die further includes a source contact on the first surface coupled to at least one of the one or more conductive patterns of the carrier submount, a gate contact on the first surface coupled to at least one of the one or more conductive patterns of the carrier submount, and a drain contact on the second surface coupled to at least one of the one or more conductive leads of the first lead frame. The second semiconductor die further includes a source contact on the first surface coupled to at least one of the one or more conductive patterns of the carrier submount and to at least one of the one or more conductive leads of the first lead frame, a gate contact on the first surface coupled to at least one of the one or more conductive patterns of the carrier submount, and a drain contact on the second surface coupled to at least one of the one or more conductive leads of the second lead frame.

Another example embodiment of the present disclosure is directed to a power semiconductor package. The power semiconductor package includes a first carrier submount, a second carrier submount, and a semiconductor die. The first carrier submount includes a first conductive layer, a second conductive layer, and an insulating layer between the first conductive layer and the second conductive layer. The semiconductor die includes a first surface and an opposing second surface. Furthermore, the first conductive layer and the second conductive layer comprise different conductive patterns.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a power semiconductor package according to example embodiments of the present disclosure.

FIG. 2 depicts a flow chart of an example method according to example embodiments of the present disclosure.

FIG. 3 depicts example direct coupling of a power semiconductor die to a first carrier submount to form a first assembly according to example embodiments of the present disclosure.

FIG. 4 depicts an example first carrier submount according to example embodiments of the present disclosure.

FIG. 5 depicts an example semiconductor die directly coupled to a first carrier submount in a flip chip configuration according to example embodiments of the present disclosure.

FIG. 6 depicts forming of an example insulating layer on the power semiconductor die according to example embodiments of the present disclosure.

FIG. 7 depicts example singulation of the first assembly(s) according to example embodiments of the present disclosure.

FIG. 8 depicts an example first assembly according to example embodiments of the present disclosure.

FIG. 9 depicts example direct coupling of a first assembly to a second carrier submount according to example embodiments of the present disclosure.

FIG. 10 depicts example encapsulating of at least a portion of the first carrier submount, second carrier submount, and power semiconductor die to form an encapsulating portion of a power semiconductor package according to example embodiments of the present disclosure.

FIG. 11 depicts a power semiconductor package according to example embodiments of the present disclosure.

FIG. 12 depicts a power semiconductor package according to example embodiments of the present disclosure.

FIG. 13 depicts a power semiconductor package according to example embodiments of the present disclosure.

FIG. 14 depicts a power semiconductor package according to example embodiments of the present disclosure.

FIG. 15 depicts a top view of an example power semiconductor package according to example embodiments of the present disclosure.

FIG. 16 depicts a cross-sectional view of a configuration of the example power semiconductor package of FIG. 15 according to example embodiments of the present disclosure.

FIG. 17 depicts a cross-sectional view of a configuration of the example power semiconductor package of FIG. 15 according to example embodiments of the present disclosure.

FIG. 18 depicts a top view of an example power semiconductor package according to example embodiments of the present disclosure.

FIG. 19 depicts a top view of an example power semiconductor package according to example embodiments of the present disclosure.

FIG. 20 depicts a cross-sectional view of a configuration of the example power semiconductor package of FIG. 19 according to example embodiments of the present disclosure.

FIG. 21 depicts a cross-sectional view of a configuration of the example power semiconductor package of FIG. 19 according to example embodiments of the present disclosure.

FIG. 22 depicts a first layer of the first carrier submount of the example power semiconductor package of FIG. 19 according to example embodiments of the present disclosure.

FIG. 23 depicts a second layer of the first carrier submount of the example power semiconductor package of FIG. 19 according to example embodiments of the present disclosure.

FIG. 24 depicts a top view of an example power semiconductor package according to example embodiments of the present disclosure.

FIG. 25 depicts a top view of an example power semiconductor package according to example embodiments of the present disclosure.

FIG. 26 depicts a cross-sectional view of a configuration of the example power semiconductor package of FIG. 25 according to example embodiments of the present disclosure.

FIG. 27 depict portions of a first lead frame and a second lead frame of the example power semiconductor package of FIG. 25 according to example embodiments of the present disclosure.

FIG. 28 depicts a carrier submount of the example power semiconductor package of FIG. 25 according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Discrete semiconductor packages have been developed that include a semiconductor die, such as a MOSFET or a Schottky diode. Such semiconductor packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Discrete semiconductor packages with Schottky diodes may be employed in many of the same high-performance power applications described above for MOSFETs, sometimes in systems that also include discrete power packages of MOSFETs.

Packaging technology for semiconductor devices plays an important role in defining the performance of the semiconductor devices. For example, the packaging of a power semiconductor die may limit the ability of the semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

Moreover, discrete semiconductor packages may use wire bond(s) (e.g., aluminum wire bond(s)) for interconnection between portions of the semiconductor die (e.g., a gate of semiconductor device) and the package (e.g., a lead frame). The use of wire bond(s) may limit the power and the ampacity accommodated by the package. Many solutions to increase power and ampacity handling capabilities of a power semiconductor package focus on high thermal conductivity materials to enhance thermal dissipation and use of a conductive clip or ribbon to make interconnections to increase ampacity. In these examples, interconnection(s) between the gate of the semiconductor device and the lead frame may still be by wire bond, which may serve as one of the weakest points in the discrete semiconductor package.

Example aspects of the present disclosure are directed to power semiconductor packages that may provide for a second thermal dissipation path for the power semiconductor die. In addition, in some examples, the power semiconductor packages do not include any wire bonds to the power semiconductor die.

More particularly, in example embodiments, a power semiconductor package may include a first carrier submount, such as a direct bonded copper (DBC) substrate or an active metal brazed (AMB) substrate. The first carrier submount may include one or more conductive pads. A power semiconductor die may be directly coupled to the first carrier submount. As used herein, the power semiconductor die is directly coupled to the first carrier submount when the power semiconductor die is attached to the first carrier submount (e.g., with or without an attach material such as solder, paste, sintered material, etc.) without any intervening structures, such as wire bonds, wire ribbons, clips, or other structures.

In some examples, the power semiconductor die is directly coupled to the first carrier submount in a flip chip configuration. In a flip chip configuration, the semiconductor die is “flipped” so that contacts associated with a typical outward facing surface of the semiconductor die (e.g., a source contact, a kelvin contact, a gate contact, etc.) are directly coupled to the first carrier submount (e.g., using an attach material).

The power semiconductor die may be based on a wide band gap semiconductor material. A wide band gap semiconductor has a band gap greater than about 1.40 eV, such as silicon carbide and/or a Group III-nitride (e.g., gallium nitride). In some examples, the power semiconductor die may include semiconductor devices, such as transistors, diodes, and/or thyristors. For instance, in some examples, the power semiconductor die may include silicon carbide-based MOSFETs, located between a source contact and a drain contact to form, for instance, a vertical structure power semiconductor device. Aspects of the present disclosure are discussed with reference to silicon carbide-based MOSFET devices for purposes of illustration and discussion. Those of ordinary skill in the art, using the disclosures provided herein, will understand that the power semiconductor die may include other power semiconductor devices without deviating from the scope of the present disclosure, such as diodes (e.g., Schottky diodes, PiN diodes, etc.), insulated gate bipolar transistors, high electron mobility transistors, or other devices.

In some examples, an insulating layer may be formed on the power semiconductor die. The insulating material may be, for instance, a dielectric material. The dielectric material may be, in some embodiments, an underfill material. The underfill material may be, for instance, a composite material made up of a polymer (e.g., epoxy polymer) with filler and/or additional components.

The semiconductor die directly coupled to the first carrier submount (e.g., in a flip chip configuration) may form a first assembly. According to examples of the present disclosure, the first assembly may be directly coupled to a second carrier submount. For instance, the opposite surface of the semiconductor die to the surface directly coupled to the first carrier submount may be directly coupled to the second carrier submount. As used herein, the power semiconductor die is directly coupled to the second carrier submount when the power semiconductor die is attached to the second carrier submount (e.g., with or without an attach material such as solder, paste, sintered material, etc.) without any intervening structures, such as wire bonds, wire ribbons, clips or other structures. In some examples, the second carrier submount may be the lead frame for the power semiconductor package and may include one or more conductive leads.

An encapsulating portion may be formed around at least a portion of the first carrier submount, the second carrier submount, and the power semiconductor die to form the power semiconductor package. In some examples, the dielectric material of the encapsulating portion may be the same as the dielectric material of the insulating layer on the power semiconductor die. In some examples, the dielectric material of the encapsulating portion may be different from the dielectric material of the insulating layer on the power semiconductor die. For instance, the dielectric material of the insulating layer may have a different dielectric constant (e.g., a lower dielectric constant) relative to the dielectric material of the encapsulating layer. In this way, the higher quality dielectric material may be used to form the insulating layer relative to the dielectric material of the encapsulating portion.

Aspects of the present disclosure provide a number of technical effects and benefits. For instance, directly coupling the power semiconductor die to both the first carrier submount and the second carrier submount provides at least two thermal dissipation paths for the power semiconductor die in the power semiconductor package. In addition, the power semiconductor die may be connected, for instance, to the lead frame of the power semiconductor package without the use of any wire bonds. The insulating layer formed on the power semiconductor die (e.g., the underfill material) may isolate the differing contacts of the power semiconductor devices on the power semiconductor die (e.g., the source contact and the drain contact) prior to coupling the power semiconductor die to the second carrier submount. This can reduce the risk of any electrical short between the source contact and the drain contact due to dielectric material processing during encapsulation.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

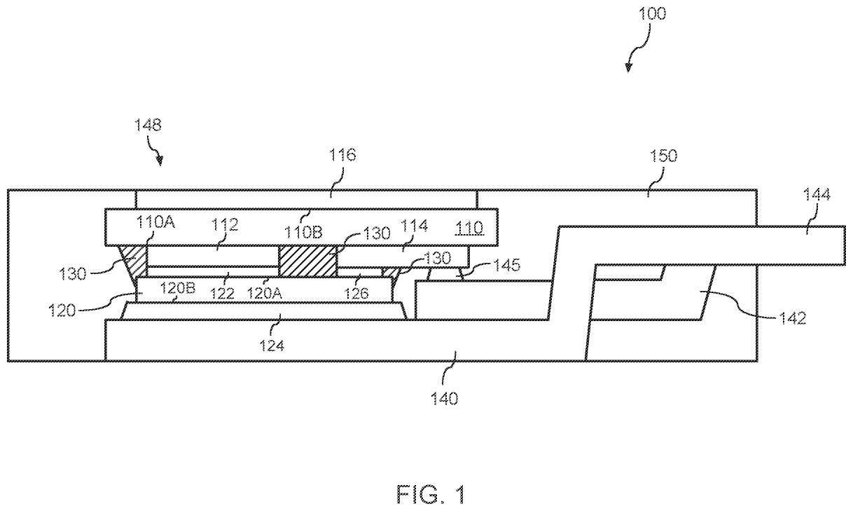

FIG. 1 depicts an example power semiconductor package 100 according to example embodiments of the present disclosure. FIG. 1 is intended to represent structures for identification and description and is not intended to represent the structures to physical scale. The power semiconductor package 100 includes a first carrier submount 110. The first carrier submount 110 may be an AMB substrate, a DBC substrate, or other suitable substrate. The first carrier submount 110 may include a dielectric and/or a ceramic substrate, such as alumina, aluminum nitride, silicon nitride, or other suitable dielectric material. The first carrier submount 110 may have a first surface 110A and an opposing second surface 110B. The first carrier submount 110 may have one or more thermally and/or electrically conductive pads on the first surface 110A. For instance, the first carrier submount 110 may have a first conductive pad 112 and a second conductive pad 114 on the first surface 110A. The first carrier submount 110 may have a thermally conductive cooling layer 116 (e.g., a copper pad) on the second surface 110B. The first conductive pad 112, the second conductive pad 114, and/or the thermally conductive cooling layer 116 may be copper, silver, gold, titanium or other conductive material.

The power semiconductor package 100 includes a power semiconductor die 120. The power semiconductor die 120 may include one or more power semiconductor devices, such as one or more transistors, diodes, thyristors, or other devices. In some examples, the power semiconductor die 120 may include a silicon carbide-based MOSFET. The power semiconductor die 120 may include a first contact 122 (e.g., a source contact) disposed on a first surface 120A of the power semiconductor die 120. The power semiconductor die 120 may include a second contact 124 (e.g., a drain contact) on a second surface 120B of the power semiconductor die that is opposite the first surface 120A. In this way, the power semiconductor die 120 may include a vertical power semiconductor device between the first contact 122 and the second contact 124.

The power semiconductor die 120 may include additional contacts. For instance, the power semiconductor die 120 may include one or more third contacts 126. The third contact(s) 126 may be on the same surface (e.g., the first surface 120A) of the power semiconductor die 120 as the first contact 122. The third contact(s) 126 may include, for instance, a gate contact and/or a kelvin contact.

The power semiconductor die 120 may be directly coupled to the first carrier submount 110. In some examples, the power semiconductor die 120 is directly coupled to the first carrier submount 110 in a flip chip configuration. For instance, a first surface 120A of the power semiconductor die 120 that includes the first contact 122 (e.g., a source contact) and the third contact 126 (e.g., a gate contact) may be directly coupled to the first carrier submount 110. A second surface 120B that is opposite the first surface 120A of the semiconductor die 120 that includes the second contact 124 (e.g., the drain contact) may be facing away from the first carrier submount 110.

More particularly, the first contact 122 (e.g., the source contact) may be directly coupled to the first conductive pad 112 of the first carrier submount 110 with or without a die-attach material (e.g., solder, paste, sintered material, etc.). The first contact 122 (e.g., the source contact) may be directly coupled to the first conductive pad 112 of the first carrier submount 110 without the use of wire bonds. The third contact 126 (e.g., the gate contact) may be directly coupled to the second conductive pad 114 of the first carrier submount 110 with or without a die-attach material (e.g., solder, paste, sintered material, etc.). The third contact 126 (e.g., the gate contact) may be directly coupled to the second conductive pad 114 of the first carrier submount 110 without the use of wire bonds.

The second contact 124 (e.g., the drain contact) may be directly coupled to a second carrier submount 140 with or without a die-attach material (e.g., solder, paste, sintered material, etc.). The second contact 124 (e.g., the drain contact) may be directly coupled to the second carrier submount 140 without the use of wire bonds. The second carrier submount 140 may include or be coupled to one or more conductive leads, such as conductive lead 142 and conductive lead 144. The conductive lead 142 and the conductive lead 144 may facilitate connection of the power semiconductor package to an external component, such as one or more circuits. The second carrier submount 140 may be, for instance, a lead frame (e.g., a copper lead frame) of the power semiconductor package 100. In some embodiments, the second carrier submount 140 may be, for instance, a substrate (e.g., a DBC substrate or an AMB substrate) that is coupled to one or more conductive leads of the power semiconductor package 100.

The one or more conductive pads on the first surface 110A of the first carrier submount 110, such as conductive pad 112 and conductive pad 114, may also be coupled to the second carrier submount 140 and/or to one or more conductive leads of (e.g., conductive lead 142) associated with the second carrier submount 140. In some examples, the conductive pad 114 on the first surface 110A of the first carrier submount 110 is coupled to the second carrier submount 140 and/or to one or more conductive leads of the second carrier submount 140 using an interconnection 145. The interconnection 145 may include, in some embodiments, an attach material (e.g., solder, paste, sintered material, etc.). The conductive pad 112 on the first surface 110A of the first carrier submount 110 may similarly be coupled to the second carrier submount 140 and/or to one or more conductive leads of the second carrier submount 140 using an interconnection (not illustrated). In some embodiments, the first conductive pad 112 may be coupled to a first conductive lead (e.g., conductive lead 142) of the second carrier submount 140. The second conductive pad 114 may be coupled to a second conductive lead of the second carrier submount 140. In this way, the first contact 122 (e.g., the source contact) and the third contact 126 (e.g., the gate contact 126) of the power semiconductor die 120 are coupled to conductive leads of the second carrier submount 140 for connection to external components.

In some examples, the power semiconductor package 100 may include an insulating layer 130 on the power semiconductor die 120. For instance, the insulating layer 130 may be on the first surface 120A of the power semiconductor die 120 having the first contact 122 (e.g., a source contact) and the third contact 126 (e.g., a gate contact). In some examples, the insulating layer 130 may extend between the power semiconductor die 120 and the first carrier submount 110, such that the insulating layer 130 fills any gaps between the power semiconductor die 120 and the first carrier submount 110. The insulating layer 130 may not extend to or may not be on the second surface 120B of the power semiconductor die 120. In some examples, the insulating layer 130 includes an underfill material. The underfill material may be, for instance, a polymer-based material, such as an epoxy polymer material. The underfill material may include a filler or other components, such as a flowing agent, adhesive agent, etc.

The semiconductor package 100 may further include an encapsulating portion 150. The encapsulating portion 150 may form a housing for the power semiconductor package 100. The encapsulating portion 150 may be formed by a molding process such that the encapsulating portion is provided at least partially around the first carrier submount 110, the power semiconductor die 120, and the second carrier submount 140. The material of the encapsulating portion 150 may electrically isolate the components within the power semiconductor package 100 from each other. The material of the encapsulating portion 150 may be a dielectric material. Example materials for the encapsulating portion 150 may include an epoxy material or an epoxy mold compound (EMC).

In some examples, the dielectric material of the encapsulating portion 150 may be the same as the dielectric material of the insulating layer 130. In some examples, the dielectric material of the encapsulating portion 150 may be different from the dielectric material of the insulating layer 130 on the power semiconductor die 120. For instance, the dielectric material of the insulating layer 130 may have a different dielectric constant (e.g., a lower dielectric constant) relative to the dielectric material of the encapsulating portion 150. In this way, a higher quality dielectric material may be used to form the insulating layer 130 relative to the dielectric material of the encapsulating portion 150.

As shown in FIG. 1, the thermally conductive cooling layer 116 on the first carrier submount 110 is exposed through the encapsulating portion 150 of the power semiconductor package 100, such as through an opening 148 in the encapsulating portion 150. As such, the thermally conductive cooling layer 116 may provide a second thermally conductive path for cooling of the power semiconductor die 120 in the power semiconductor package 100. More particularly, the first thermally conductive path may be provided through the second carrier submount 140 and the one or more conductive leads, such as conductive lead 142 and conductive lead 144. The second thermally conductive path may be provided through opening 148 in the encapsulating portion 150 that leaves at least a portion of the thermally conductive cooling layer 116 exposed through the encapsulating portion 150. The thermally conductive cooling layer 116 may be coupled to a heat sink and/or may provide a thermally conductive path to an ambient environment of the power semiconductor package 100.

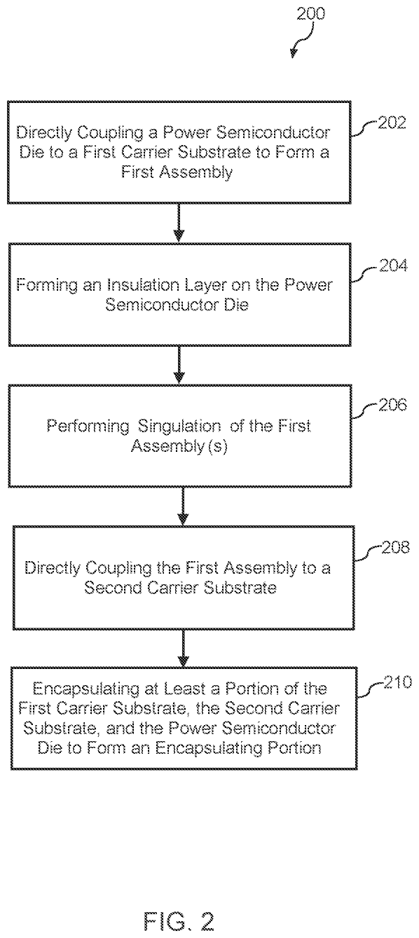

FIG. 2 depicts a flow chart of an example method for fabricating a power semiconductor package according to example embodiments of the present disclosure, such as the power semiconductor packages depicted in FIGS. 1, 11, and 12. FIG. 2 depicts steps performed in a particular order for purposes of illustration and discussion. Those of ordinary skill in the art, using the disclosures provided herein, will understand that the various steps provided in this disclosure may be omitted, rearranged, expanded, include steps not illustrated, and/or modified in various ways without deviating from the scope of the present disclosure.

At 202, the method 200 may include directly coupling a power semiconductor die to a first carrier submount to form a first assembly. For instance, in some examples, a plurality of power semiconductor die may be subjected to singulation from a semiconductor wafer to provide a plurality of individual power semiconductor die. Each individual power semiconductor die may be, for instance, the power semiconductor die 120 discussed with reference to FIG. 1. Each power semiconductor die may include one or more power semiconductor devices, such as transistors, diodes, thyristors, etc. As described above, the power semiconductor die may include wide band gap semiconductor. The power semiconductor die may include a vertical power semiconductor device including a first contact arranged on a first surface and a second contact arranged on an opposing second surface of the power semiconductor die. As an example, the power semiconductor die may include one or more silicon carbide-based MOSFETs. In some examples, each of the plurality of power semiconductor die may be directly coupled to a carrier sheet or card having a plurality of first carrier submounts arranged in a grid or an array.

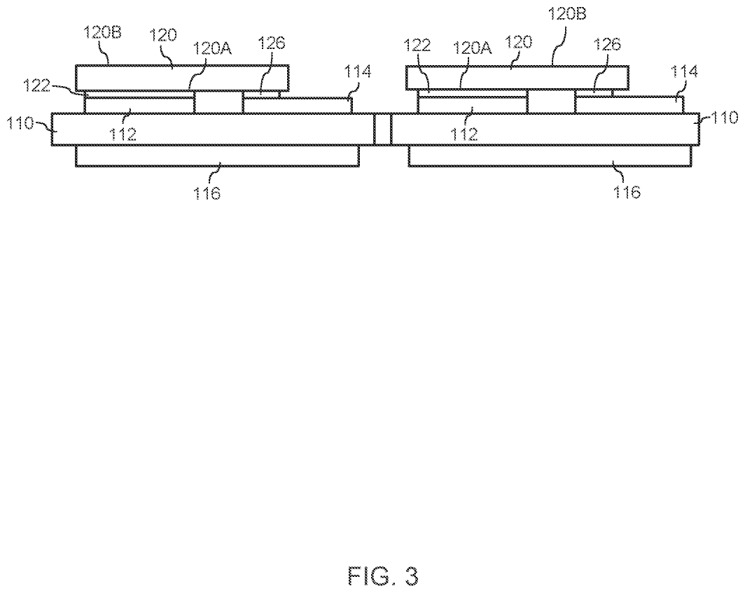

FIG. 3 depicts the direct coupling of a plurality of power semiconductor die 120 to a carrier sheet having a plurality of first carrier submounts 110 according to example embodiments of the present disclosure. As shown, the power semiconductor die are directly coupled to the first carrier submounts 110 (e.g., with or without an attach material) using a flip chip configuration. In the flip chip configuration, the first surface 120A of the power semiconductor die including a first contact 122 (e.g., a source contact) and the third contact 126 (e.g., a gate contact) are “flipped” and directly coupled to conductive pads on the first carrier submount 110. For instance, the first contact 122 (e.g., a source contact) is coupled to a first conductive pad 112. The third contact 126 (e.g., a gate contact) is coupled to a second conductive pad 114. No wire bonds are used to couple the power semiconductor die 120 to the first carrier submounts 110. The combination of the power semiconductor die 120 directly coupled to one of the plurality of first carrier submounts 110 may be a first assembly 160.

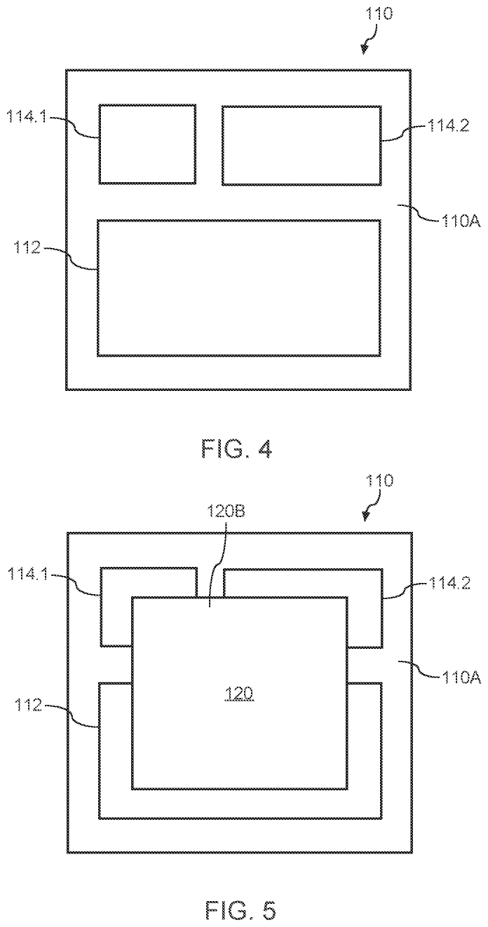

FIGS. 4 and 5 depict plan views of the example direct coupling of a power semiconductor die 120 to a first carrier submount 110 using a flip chip configuration according to example embodiments of the present disclosure. FIG. 4 depicts a plan view of the first surface 110A of an example first carrier submount 110. The first carrier submount 110 includes a patterned arrangement of conductive pads, including first conductive pad 112 and second conductive pads 114.1 and 114.2. The first conductive pad 112 may be for direct coupling of a source contact of a power semiconductor die 120. The second conductive pad 114.1 may be for direct coupling of a gate contact of a power semiconductor die 120. The second conductive pad 114.2 may be for direct coupling of other contacts of a power semiconductor die 120 (e.g., a kelvin contact).

FIG. 5 depicts a plan view of the power semiconductor die 120 directly coupled to the first carrier submount 110. As shown, the power semiconductor die 120 is flipped so that the first surface 120A (not illustrated) including the first contact 122 (e.g. source contact) and the third contact 126 (e.g., gate contact) are face down and coupled to the first carrier submount 110. The second surface 120B of the power semiconductor die 120 including the second contact (e.g., drain contact) is face up facing a direction away from the first carrier submount 110.

FIGS. 4 and 5 depict one example pattern of conductive pads for the first carrier submount 110 for purposes of illustration and discussion. Those of ordinary skill in the art, using the disclosures provided herein, will understand that the first carrier submount 110 may include a variety of different patterns or arrangements of conductive pads without deviating from the scope of the present disclosure.

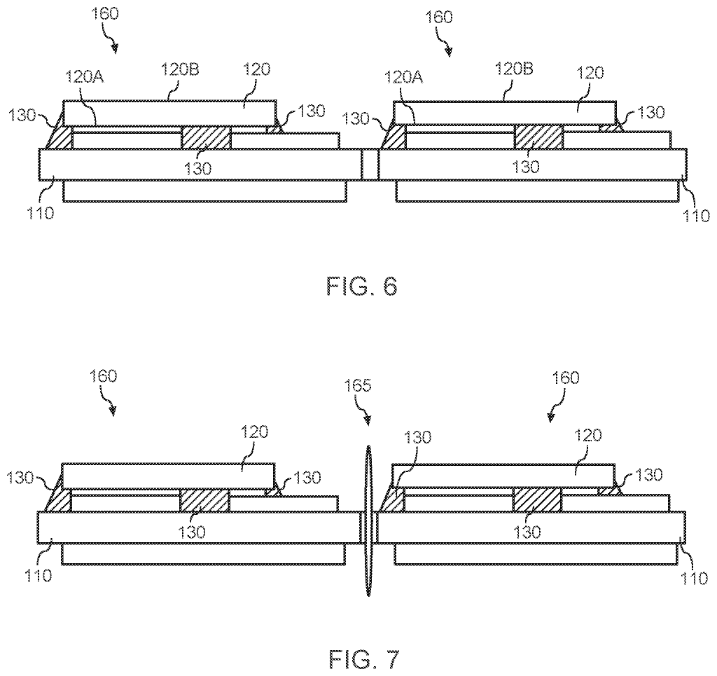

Referring to FIG. 2 at 204, the method 200 may include forming an insulating layer on the power semiconductor die of the first assembly. For instance, as shown in FIG. 6, an insulating layer 130 may be formed on the first assembly 160. More particularly, the insulating layer 130 may be formed on the power semiconductor die 120 to cover at least a portion of the first contact 122 (e.g., source contact) and the third contact 126 (e.g., gate contact). The insulating layer 130 may fill any gaps between the power semiconductor die 120 and the first carrier submount 110. The insulating layer 130 may only be on only one surface of the power semiconductor die 120, such as the first surface 120A of the power semiconductor die 120 directly coupled to the first carrier submount 110. In some examples, the insulating layer 130 includes an underfill material. The underfill material may be, for instance, a polymer-based material, such as an epoxy polymer material. The underfill material may include a filler or other components, such as a flowing agent, adhesive agent, etc.

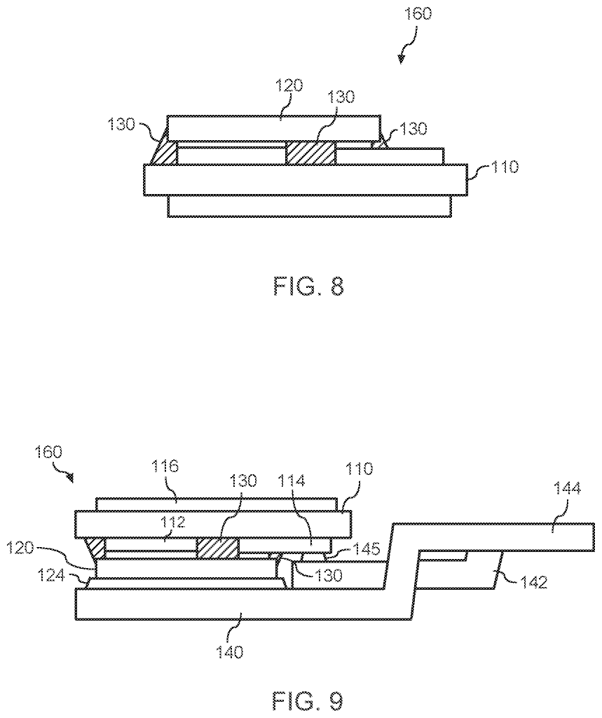

Referring to FIG. 2 at 206, the method 200 may include performing singulation of the first assembly(s). For instance, as shown in FIG. 7, a cutting tool 165 may be used to separate the first assembly(s) 160 from one another in the carrier sheet. FIG. 8 depicts an example individual first assembly 160 after singulation. Each individual first assembly 160 includes a power semiconductor die 120 directly coupled to a first carrier submount 110, for instance, in a flip chip configuration, with an insulating layer 130 on the power semiconductor die 120.

Referring to FIG. 2 at 208, the method 200 may include directly coupling the first assembly to a second carrier submount. For instance, as shown in FIG. 9, the first assembly 160 is “flipped” and directly coupled to a second carrier submount 140 that includes one or more conductive leads, such as conductive lead 142 and conductive lead 144. The second carrier submount 140, in some examples, may be a lead frame for a power semiconductor package. As shown in FIG. 9, the second contact 124 (e.g., drain contact) of the power semiconductor die 120 is directly coupled to the second carrier submount (e.g., with or without an attach material) without the use of wire bonds. In addition, one or more conductive pads on the first carrier submount 110 are also coupled to the second carrier submount 140. For instance, referring to FIGS. 4 and 5 conductive pad 114.1 may be coupled to the second carrier submount 140 and/or to one or more conductive leads (e.g., conductive lead 142) of the second carrier submount 140 through an interconnection (e.g., interconnection 145, such as an attach material). The conductive pad 114.2 may be coupled to the second carrier submount 140 and/or to one or more conductive leads of the second carrier submount 140 through an interconnection (e.g., attach material). The conductive pad 112 may be coupled to the second carrier submount 140 and/or to one or more conductive leads of the second carrier submount 140 through an interconnection (e.g., attach material)). In this way, the power semiconductor die 120 is directly coupled to two different carrier submounts without wire bonds to establish connections to conductive leads of a power semiconductor package.

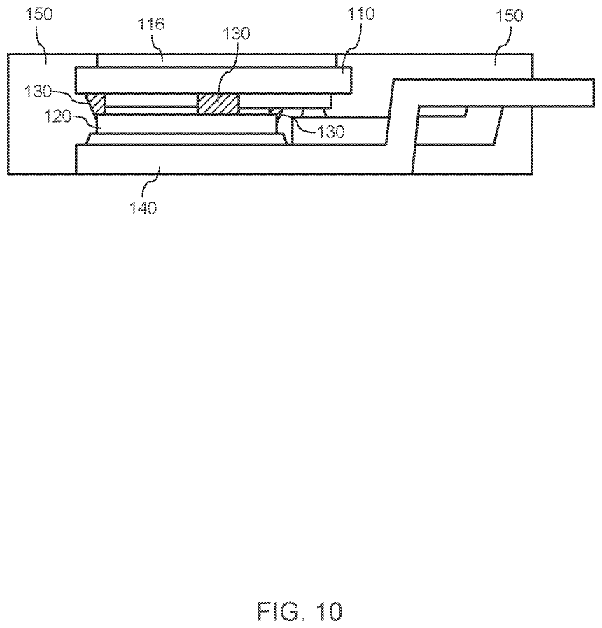

Referring to FIG. 2 at 210, the method 200 may include encapsulating at least a portion of the first carrier submount, the second carrier submount, and the power semiconductor die to form an encapsulating portion. For instance, as shown in FIG. 10, an encapsulating portion 150 may be formed at least partially covering the first carrier submount 110, the power semiconductor die 120, the insulating layer 130, and the second carrier submount 140. The encapsulating portion 150 may form a housing for the power semiconductor package 100. The encapsulating portion 150 may be formed by a molding process such that the encapsulating portion is provided at least partially around the first carrier submount 110, the semiconductor die 120, and the second carrier submount 140. The material of the encapsulating portion 150 may electrically isolate the components within the encapsulating portion 150 from each other. The material of the encapsulating portion 150 may be a dielectric material. Example materials for the encapsulating portion 150 may include an epoxy material or an epoxy mold compound (EMC).

In some examples, the dielectric material of the encapsulating portion 150 may be the same as the dielectric material of the insulating layer 130. In some examples, the dielectric material of the encapsulating portion 150 may be different from the dielectric material of the insulating layer 130 on the power semiconductor die 120. For instance, the dielectric material of the insulating layer 130 may have a different dielectric constant (e.g., a lower dielectric constant) relative to the dielectric material of the encapsulating portion 150. In this way, a higher quality dielectric material may be used to form the insulating layer 130 relative to the dielectric material of the encapsulating portion 150.

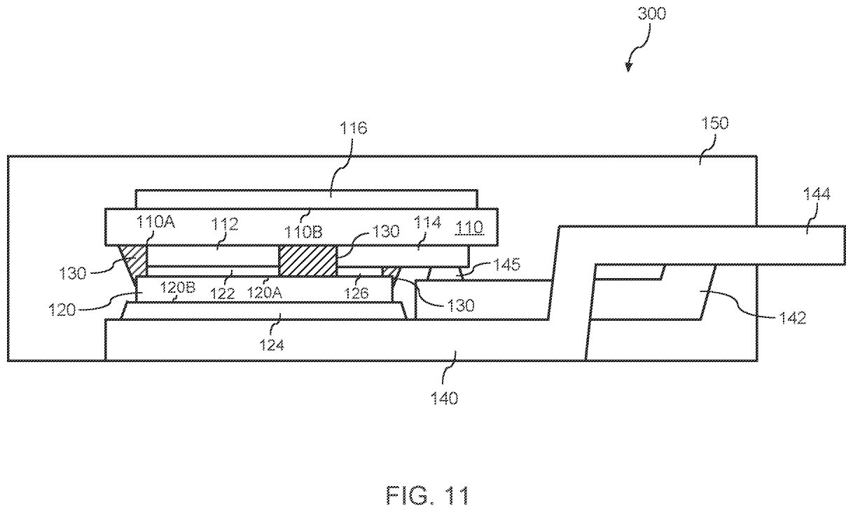

Variations and modifications may be made to the example power semiconductor packages described herein without deviating from the scope of the present disclosure. For instance, FIG. 11 depicts a power semiconductor package 300 that is similar to the power semiconductor package 100 of FIG. 1. FIG. 11 is intended to represent structures for identification and description and is not intended to represent the structures to physical scale. For instance, the power semiconductor package 300 includes a first carrier submount 110. The first carrier submount 110 includes one or more conductive pads (e.g., conductive pads 112 and 114) and a thermally conductive cooling layer 116. The power semiconductor package 300 includes a second carrier submount 140. The second carrier submount 140 includes one or more conductive leads (e.g., conductive lead 142 and conductive lead 144) for the power semiconductor package 300. The power semiconductor package 300 includes a power semiconductor die 120 having a first surface 120A and an opposing second surface 120B. The first surface 120A of the power semiconductor die 120 is directly coupled to the first carrier submount 110 (e.g., in a flip chip configuration). The second surface 120B of the power semiconductor die 120 is directly coupled to the second carrier submount 140.

In the power semiconductor package 300, the first carrier submount 110 includes a thermally conductive cooling layer 116 on the second surface 110B of the first carrier submount 110 opposite the first surface 110A with the one or more conductive pads (e.g., conductive pads 112 and 114). In the example of FIG. 11, the thermally conductive cooling layer 116 is covered by the encapsulating portion 150 instead of being exposed through an opening of the encapsulating portion 150.

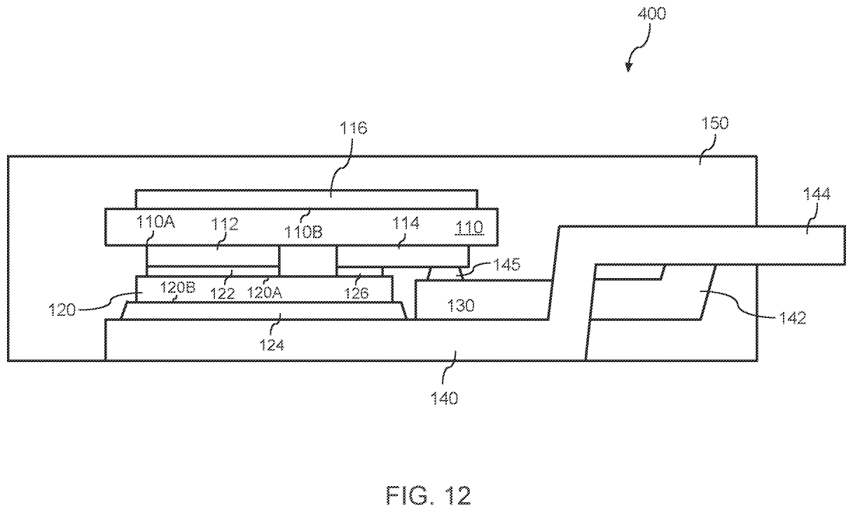

FIG. 12 depicts a power semiconductor package 400 that is similar to the power semiconductor package 100 of FIG. 1 and the power semiconductor package 300 of FIG. 11. FIG. 12 is intended to represent structures for identification and description and is not intended to represent the structures to physical scale. The power semiconductor package 400 includes a first carrier submount 110. The first carrier submount 110 includes one or more conductive pads (e.g., conductive pads 112 and 114) and a thermally conductive cooling layer 116. The power semiconductor package 400 includes a second carrier submount 140. The second carrier submount 140 includes one or more conductive leads (e.g., conductive lead 142 and conductive lead 144) for the power semiconductor package 400. The power semiconductor package 400 includes a power semiconductor die 120 having a first surface 120A and an opposing second surface 120B. The first surface 120A of the power semiconductor die 120 is directly coupled to the first carrier submount 110 (e.g., in a flip chip configuration). The second surface 120B of the power semiconductor die 120 is directly coupled to the second carrier submount 140. The power semiconductor package 400 does not include a separate insulating layer 130 on the power semiconductor die 120. Rather, the encapsulating portion 150 of the power semiconductor package 400 surrounds the power semiconductor die 120.

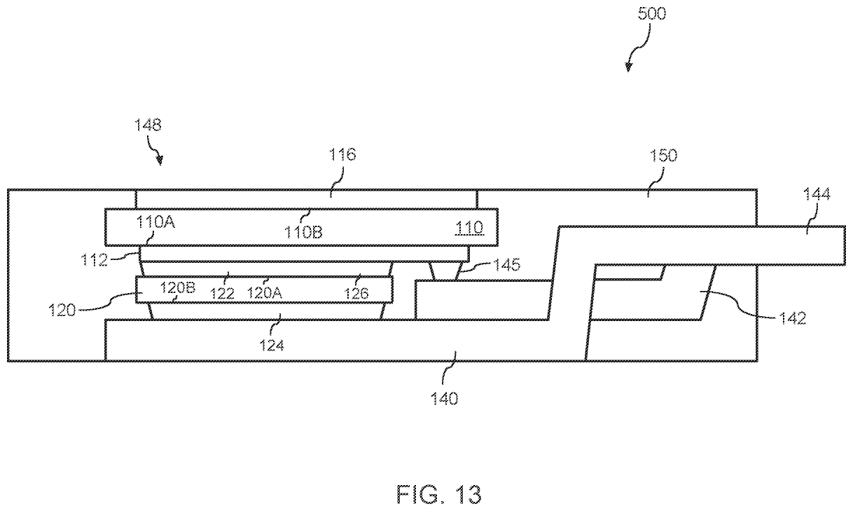

FIG. 13 depicts a power semiconductor package 500 that is similar to the power semiconductor package 100 of FIG. 1. FIG. 13 is intended to represent structures for identification and description and is not intended to represent the structures to physical scale. For instance, the power semiconductor package 500 includes a first carrier submount 110. The first carrier submount 110 includes one or more conductive pads (e.g., conductive pad 112) and a thermally conductive cooling layer 116. The power semiconductor package 500 includes a second carrier submount 140. The second carrier submount 140 includes one or more conductive leads (e.g., conductive lead 142 and conductive lead 144) for the power semiconductor package 500. The power semiconductor package 500 includes a power semiconductor die 120. In the example of FIG. 13, the power semiconductor die 120 may include one or more Schottky diodes, such as one or more silicon carbide-based Schottky diodes. The power semiconductor die 120 has a first surface 120A and an opposing second surface 120B. The first surface 120A of the power semiconductor die 120 is directly coupled to the first carrier submount 110 (e.g., in a flip chip configuration) such that a first contact 122 (e.g., an anode contact) is directly coupled to the first carrier submount 110. The second surface 120B of the power semiconductor die 120 is directly coupled to the second carrier submount 140 such that a second contact 124 (e.g., a cathode contact) is directly coupled to the second carrier submount 140. The power semiconductor package 500 includes an encapsulating portion 150. The thermally conductive cooling layer 116 is exposed through an opening 148 in the encapsulating portion 150.

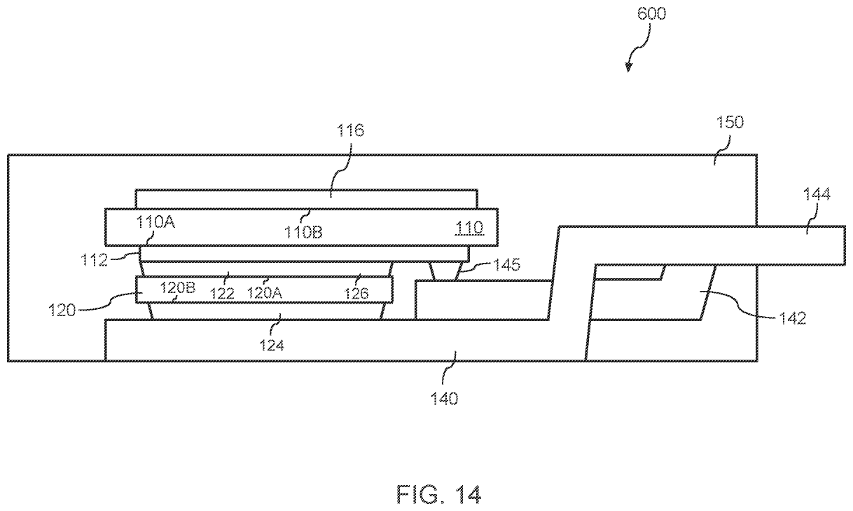

FIG. 14 depicts a power semiconductor package 600 that is similar to the power semiconductor package 500 of FIG. 13. FIG. 14 is intended to represent structures for identification and description and is not intended to represent the structures to physical scale. For instance, the power semiconductor package 600 includes a first carrier submount 110. The first carrier submount 110 includes one or more conductive pads (e.g., conductive pad 112) and a thermally conductive cooling layer 116. The power semiconductor package 600 includes a second carrier submount 140. The second carrier submount 140 includes one or more conductive leads (e.g., conductive lead 142 and conductive lead 144) for the power semiconductor package 600. The power semiconductor package 600 includes a power semiconductor die 120. In the example of FIG. 14, the power semiconductor die 120 may include one or more Schottky diodes, such as one or more silicon carbide-based Schottky diodes. The power semiconductor die 120 has a first surface 120A and an opposing second surface 120B. The first surface 120A of the power semiconductor die 120 is directly coupled to the first carrier submount 110 (e.g., in a flip chip configuration) such that a first contact 122 (e.g., an anode contact) is directly coupled to the first carrier submount 110. The second surface 120B of the power semiconductor die 120 is directly coupled to the second carrier submount 140 such that a second contact 124 (e.g., a cathode contact) is directly coupled to the second carrier submount 140. The power semiconductor package 600 includes an encapsulating portion 150. A thermal cooling layer 116 is covered by the encapsulating portion 150.

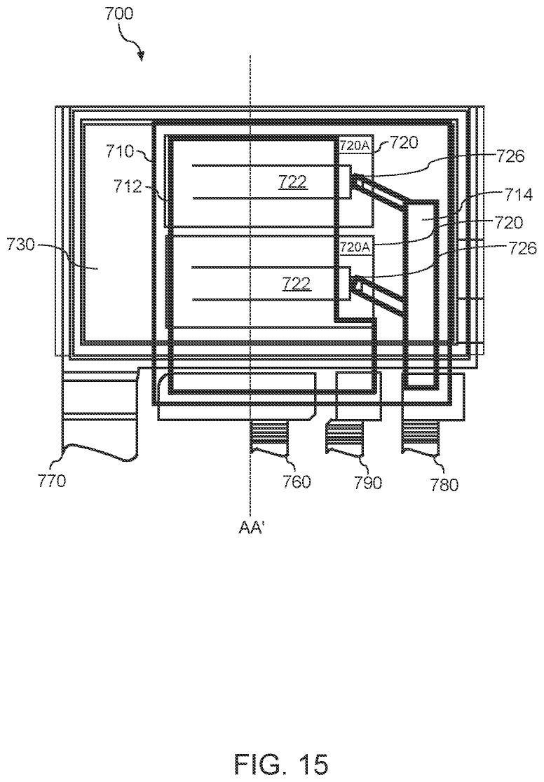

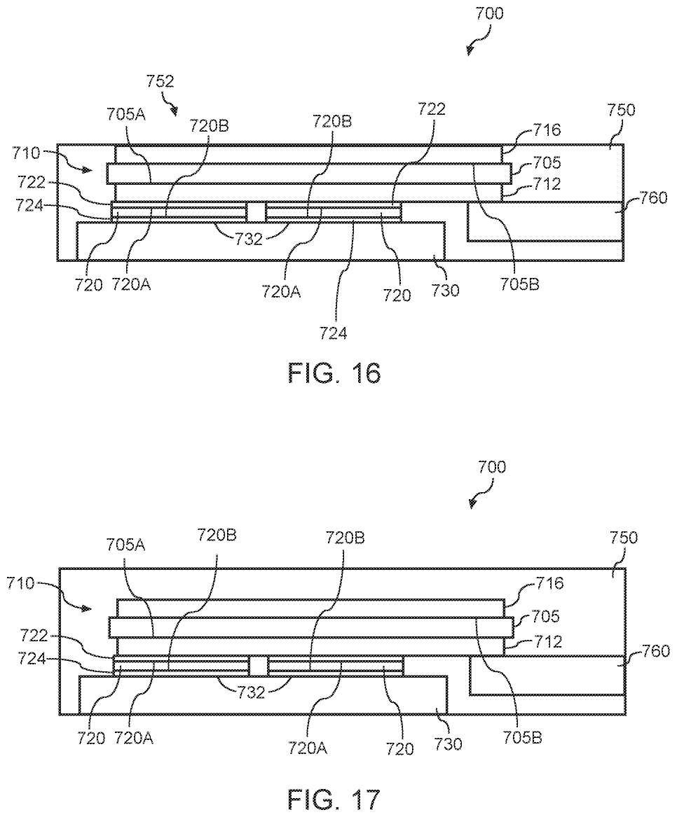

FIGS. 15-17 depict an example power semiconductor package 700 according to example embodiments of the present disclosure. FIG. 15 depicts a top view of the power semiconductor package 700, and FIGS. 16-17 depict a cross-sectional view of the power semiconductor package 700 taken along the line AA′ shown in FIG. 15. FIGS. 15-17 are intended to represent structures for identification and description and is not intended to represent the structures to physical scale.

The power semiconductor package 700 includes a first carrier submount 710. The first carrier submount 710 may be an active metal brazed (AMB) substrate, a direct bonded copper (DBC) substrate, or other suitable substrate. The first carrier submount 710 may include a dielectric and/or a ceramic substrate, such as alumina, aluminum nitride, silicon nitride, or other suitable dielectric material.

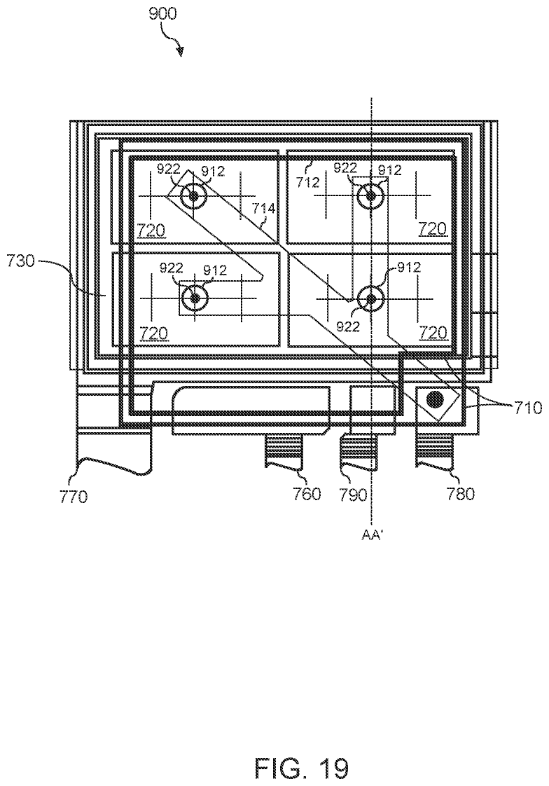

The first carrier submount 710 may have an insulating layer 705 with a first surface 705A and an opposing second surface 705B. The first carrier submount 710 may have one or more thermally and/or electrically conductive patterns, such as conductive pattern 712 and conductive pattern 714, on the first surface 705A of the insulating layer 705. In this manner, conductive patterns 712 and 714 may be disposed on the same layer of the first carrier submount 710. However, as will be discussed in greater detail below (e.g., FIGS. 19-23), conductive patterns 712 and 714 may be disposed on different layers of the first carrier submount 710 without deviating from the scope of the present disclosure. The one or more conductive patterns, such as conductive pattern 712 and conductive pattern 714, may be copper, silver, gold, titanium, or other suitable conductive material. The first carrier submount 710 may have a thermally conductive cooling layer 716 (e.g., a copper pad) on the second surface 705B of the insulating layer 705. The thermally conductive cooling layer 716 may be copper, silver, gold, titanium, or other suitable conductive material.

The power semiconductor package 700 includes a plurality of semiconductor die 720. As shown, in some embodiments, each of the plurality of semiconductor die 720 may be arranged in a parallel configuration within the power semiconductor package 700. In other embodiments, however, each of the plurality of semiconductor die 720 may be arranged in a series configuration within the power semiconductor package 700 without deviating from the scope of the present disclosure. It should be understood that, as used herein, a “plurality” means “at least two” and/or “two or more.”

The semiconductor die 720 may include one or more power semiconductor devices, such as one or more transistors, diodes, thyristors, or other devices. In some embodiments, the plurality of semiconductor die 720 may be a plurality of wide bandgap semiconductor die 720. For instance, the plurality of wide bandgap semiconductor die 720 may include silicon carbide. More specifically, each of the plurality of wide bandgap semiconductor die 720 may include a silicon carbide-based MOSFET. Additionally and/or alternatively, each of the plurality of wide bandgap semiconductor die 720 may include a silicon carbide-based Schottky diode. Furthermore, the silicon carbide-based MOSFETs of the plurality of semiconductor die and/or the silicon carbide-based Schottky diodes of the plurality of semiconductor die may be arranged in parallel and/or in series. As will be discussed in greater detail below, the power semiconductor package 700 may not include any wire bonds to any of the plurality of semiconductor die 720.

It should be noted that the power semiconductor package 700 is depicted in FIGS. 15-17 with two semiconductor die 720 for purposes of illustration and discussion. For instance, in some examples, a number of semiconductor die included in the plurality of semiconductor die 720 may be in a range of, for instance, two semiconductor die to nine semiconductor die. However, those having ordinary skill in the art, using the disclosures provided herein, will understand that any suitable number of semiconductor die 720 may be used without deviating from the scope of the present disclosure.

Each semiconductor die 720 of the plurality of semiconductor die 720 may include a first contact 722 (e.g., a source contact) disposed on a first surface 720A of the semiconductor die 720. Each semiconductor die 720 of the plurality of semiconductor die 720 may include a second contact 724 (e.g., a drain contact) disposed on a second surface 720B of the semiconductor die 720 that is opposite the first surface 720A. In this way, each semiconductor die 720 may include a vertical semiconductor device between the respective first contact 722 and second contact 724.

Each semiconductor die 720 of the plurality of semiconductor die 720 may include additional contacts. For instance, each semiconductor die 720 may include one or more third contacts 726. The third contact(s) 726 may be on the same surface (e.g., first surface 720A) of the respective semiconductor die 720 as the first contact 722. The third contact(s) 726 may include, for instance, a gate contact and/or a kelvin contact.

The power semiconductor package 700 further includes a second carrier submount 730. The second carrier submount 730 may include, or be coupled to, one or more conductive leads, such as conductive lead 732. The conductive lead(s) may facilitate connection of the power semiconductor package 700 to an external component, such as one or more circuits. The second carrier submount 730 may be, for instance, a lead frame (e.g., copper lead frame) of the power semiconductor package 700. In some embodiments, the second carrier submount 730 may be, for instance, a substrate (e.g., a DBC substrate or an AMB substrate) that is coupled to one or more conductive leads 732 of the power semiconductor package 700.

Each semiconductor die 720 may be directly coupled to the first carrier submount 710. In some examples, each semiconductor die 720 may be directly coupled to the first carrier submount 710 in a flip chip configuration. For instance, for each semiconductor die 720, the first surface 720A (e.g., surface that includes the first contact 722 and the third contact 726) may be directly coupled to the first carrier submount 710, and the second surface 720B (e.g., surface that includes the second contact 724) that is opposite the first surface 720A may be facing away from the first carrier submount 710. In some embodiments, the second surface 720B of each of the plurality of semiconductor die 720 may be directly coupled to the second carrier submount 730.

More specifically, for each semiconductor die 720, the first contact 722 (e.g., source contact) may be directly coupled to at least one of the one or more conductive patterns of the first carrier submount 710, such as conductive pattern 712, with or without a die-attach material (e.g., solder, paste, sintered material, etc.). Furthermore, for each semiconductor die 720, the first contact 722 (e.g., source contact) may be directly coupled to at least one of the one or more conductive patterns of the first carrier submount 710, such as conductive pattern 712, without the use of wire bonds. Additionally, as shown in FIGS. 15-17, each first contact 722 of each semiconductor die 720 may be coupled to the same conductive pattern (e.g., conductive pattern 712). Alternatively, as will be discussed in greater detail below, each first contact 722 of each semiconductor die 720 may be coupled to a different conductive pattern of the one or more conductive patterns of the first carrier submount 710.

For each semiconductor die 720, the third contact 726 (e.g., gate contact) may be directly coupled to at least one of the one or more conductive patterns of the first carrier submount 710, such as conductive pattern 714, with or without a die-attach material (e.g., solder, paste, sintered material, etc.). Furthermore, for each semiconductor die 720, the third contact 726 (e.g., gate contact) may be directly coupled to at least one of the one or more conductive patterns of the first carrier submount 710, such as conductive pattern 714, without the use of wire bonds. In this manner, for each semiconductor die 720, the first contact 722 (e.g., source contact) and the third contact 726 (e.g., gate contact) may be coupled to different conductive patterns of the one or more conductive patterns (e.g., conductive pattern 712 and conductive pattern 714, respectively). In the example of FIG. 15, the conductive pattern 712 and the conductive pattern 714 are on the same conductive layer of the first carrier submount 710. As will be discussed with reference to FIG. 19-23, the conductive pattern 712 associated with making a source connection and the conductive pattern 714 associated with making a gate connection may be on different layers of the first carrier submount 710.

For each semiconductor die 720, the second contact 724 (e.g., drain contact) may be directly coupled to the second carrier submount 730 with or without a die-attach material (e.g., solder, paste, sintered material, etc.). Furthermore, for each semiconductor die 720, the second contact 724 (e.g., drain contact) may be directly coupled to the second carrier submount 730 with or without the use of wire bonds. Additionally, as shown in FIGS. 15-17, each second contact 724 of each semiconductor die 720 may be coupled to the same conductive lead (e.g., conductive lead 732). Alternatively, as will be discussed in greater detail below, each second contact 724 of each semiconductor die 720 may be coupled to a different conductive lead of the one or more conductive leads of the second carrier submount 730.

The power semiconductor package 700 may include an insulating layer (not shown) on the plurality of semiconductor die 720. More particularly, the power semiconductor package 700 may include an insulating layer on the plurality of semiconductor die 720 that is similar to the insulating layer 130 discussed above with reference to FIG. 1. For instance, the insulating layer may be on the first surface 720A of each of the plurality of semiconductor die 720 that includes first contact 722 (e.g., source contact) and the third contact (e.g., gate contact). Additionally, the insulating layer may extend between the plurality of semiconductor die 720 and the first carrier submount 710, such that the insulating layer fills any gaps between the plurality of semiconductor die 720 and the first carrier submount 710. The insulating layer may not extend to, or may not be on, the second surface 720B of each of the plurality of semiconductor die 720. In some embodiments, the insulating layer includes an underfill material. The underfill material may be, for instance, a polymer-based material, such as an epoxy polymer material. The underfill material may include a filler or other components, such as a flowing agent, adhesive agent, etc.

The power semiconductor package 700 may further include an encapsulating portion 750. The encapsulating portion 750 may form a housing for the power semiconductor package 700. The encapsulating portion 750 may be formed by a molding process such that the encapsulating portion is provided at least partially around the first carrier submount 710, the plurality of semiconductor die 720, and the second carrier submount 730. The material of the encapsulating portion 750 may electrically isolate the components within the power semiconductor package 700 from each other. The material of the encapsulating portion 750 may be a dielectric material. Example materials for the encapsulating portion 750 may include an epoxy material or an epoxy mold compound (EMC).

In some examples, the dielectric material of the encapsulating portion 750 may be the same as the dielectric material of the insulating layer. In some examples, the dielectric material of the encapsulating portion 750 may be different from the dielectric material of the insulating layer on the plurality of semiconductor die 720. For instance, the dielectric material of the insulating layer may have a different dielectric constant (e.g., a lower dielectric constant) relative to the dielectric material of the encapsulating portion 750. In this way, a higher quality dielectric material may be used to form the insulating layer relative to the dielectric material of the encapsulating portion 750.

In some embodiments, such as that shown in FIG. 16, the thermally conductive cooling layer 716 of the first carrier submount 710 may be exposed through the encapsulating portion 750. More particularly, the thermally conductive cooling layer 716 may be exposed through an opening 752 in the encapsulating portion 750. As such, the thermally conductive cooling layer 716 may provide a second thermally conductive path for cooling of the plurality of semiconductor die 720 in the power semiconductor package 700. More particularly, the first thermally conductive path may be provided through the second carrier submount 730 and the one or more conductive leads, such as conductive lead 732. The second thermally conductive path may be provided through opening 752 in the encapsulating portion 750. The thermally conductive cooling layer 716 may be coupled to a heat sink and/or may provide a thermally conductive path to an ambient environment of the power semiconductor package 700.

In other embodiments, such as that shown in FIG. 17, the thermally conductive cooling layer 716 of the first carrier submount 710 may be covered by the encapsulating portion 150, rather than being exposed through an opening (e.g., opening 752) of the encapsulating portion 150 as depicted in FIG. 16. As such, the first thermally conductive path may be provided through the second carrier submount 730 and the one or more conductive leads, such as conductive lead 732.

Referring again to FIGS. 15-17, as noted above, each first contact 722 (e.g., source contact) of each semiconductor die 720 may be coupled to the same conductive pattern (e.g., conductive pattern 712) of the first carrier submount 710, and each second contact 724 (e.g., drain contact) of each semiconductor die 720 may be coupled to the same conductive lead (e.g., conductive lead 732) of the second carrier submount 730. In this manner, each semiconductor die 720 of the plurality of semiconductor die 720 may be coupled to a common source terminal 760 (via respective first contact 722) and to a common drain terminal 770 (via respective second contact 724). Similarly, each semiconductor 720 may be coupled to a common gate terminal 780 and/or a common kelvin terminal 790 via the respective third contact 726.

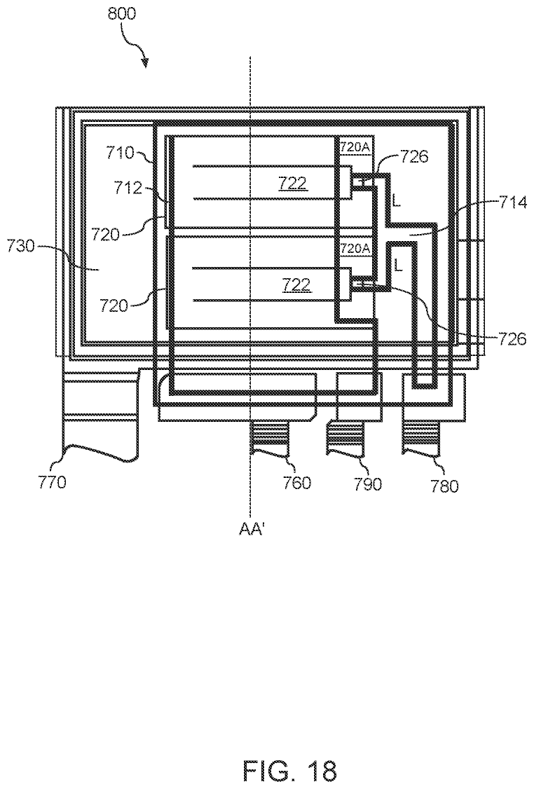

FIG. 18 depicts a power semiconductor package 800 that is similar to the power semiconductor package 700 discussed above with reference to FIGS. 15-17. FIG. 18 is intended to represent structures for identification and description and is not intended to represent the structures to physical scale. The power semiconductor package 800 includes a first carrier submount 710. The first carrier submount 710 includes one or more conductive patterns (e.g., conductive pattern 712) and a thermally conductive cooling layer 716. The power semiconductor package 800 includes a second carrier submount 730. The second carrier submount 730 includes one or more conductive leads (e.g., conductive lead 732) for the power semiconductor package 800.

The power semiconductor package 800 includes a plurality of semiconductor die 720. Each semiconductor die 720 includes a first surface 720A and an opposing second surface 720B. The first surface 720A of each of the semiconductor die 720 is directly coupled to the first carrier submount 710 (e.g., in a flip chip configuration) such that a first contact 722 (e.g., source contact) and a third contact 726 (e.g., gate contact) are directly coupled to the first carrier submount 710. The second surface 720B of each of the semiconductor die 720 is directly coupled to the second carrier submount 730 such that a second contact 724 (e.g., drain contact) is directly coupled to the second carrier submount 730. In this manner, each semiconductor die 720 of the plurality of semiconductor die 720 may be coupled to a common source terminal 760 (via respective first contact 722), to a common drain terminal 770 (via respective second contact 724), and to a common gate terminal 780.

It should be noted that the two semiconductor die 720 depicted in FIG. 18 are arranged in a parallel configuration for purposes of illustration and discussion. The power semiconductor package 800 may include more than two semiconductor die 720 and/or less than two semiconductor die 720 arranged in a parallel configuration and/or a series configuration without deviating from the scope of the present disclosure.

The power semiconductor package 800 includes an encapsulating portion 750. In some embodiments, the thermally conductive cooling layer 716 is exposed through an opening 752 in the encapsulating portion. Additionally and/or alternatively, in some embodiments, the thermally conductive cooling layer 716 may be covered by the encapsulating portion 750.

In the example of FIG. 18, the conductive pattern 714 is arranged in the power semiconductor package 800 such that a gate signal routing length L for each of the semiconductor die 720 is substantially the same. More specifically, as shown in FIG. 18, the gate signal routing length L between the gate terminal 780 and each semiconductor die 720, respectively, is the same. By matching the gate signal routing length L for each semiconductor die 720, various electrical characteristics (e.g., resistance, inductance) along the gate signal routing path to each semiconductor die 720 is likewise matched, which ultimately results in increased current balance between the plurality of semiconductor die 720.

For instance, in some embodiments, each semiconductor die 720 may include a wide bandgap semiconductor device, such as a silicon carbide-based MOSFET. In such embodiments, by matching the gate signal routing length L between the gate terminal 780 and each MOSFET, the current balance between the MOSFETs during switching transitions (e.g., turn-on, turn-off) is increased.

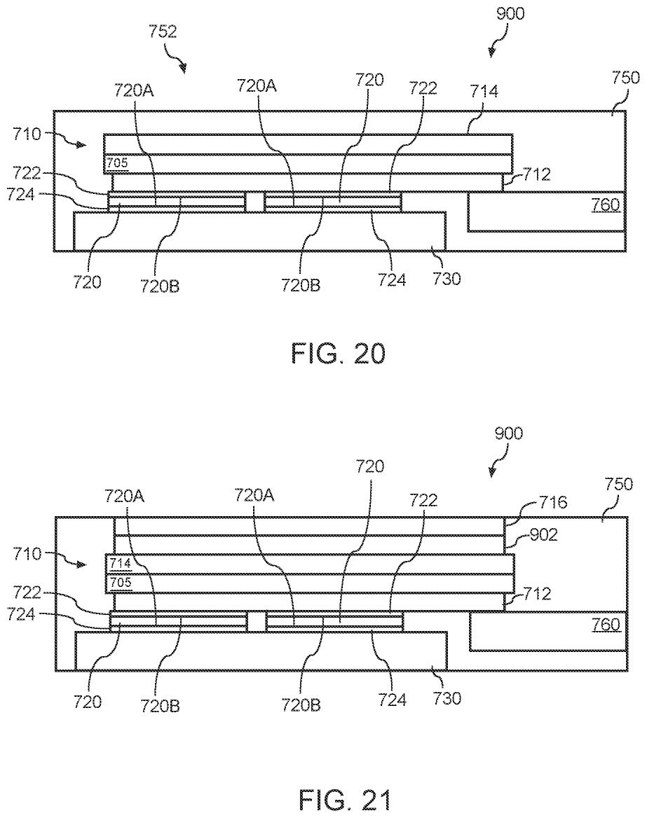

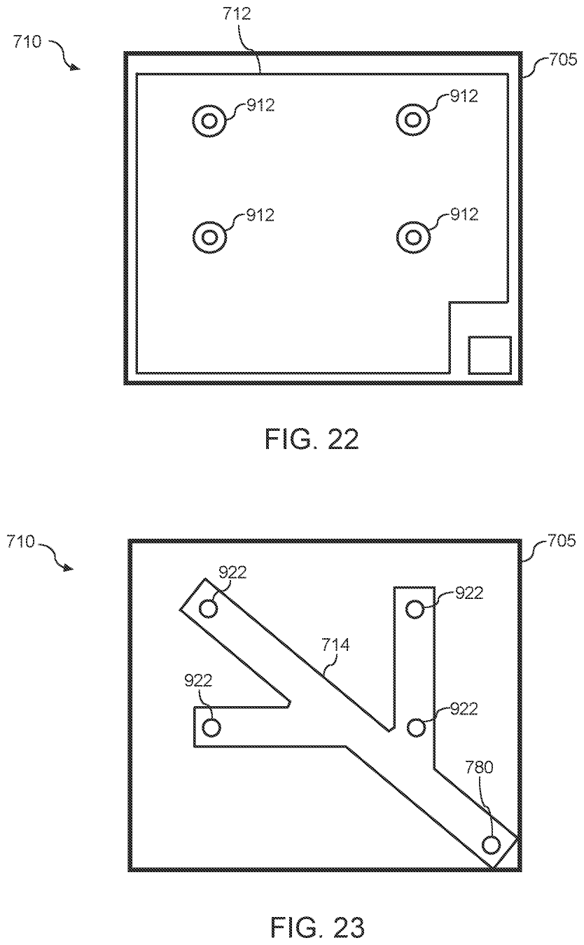

FIGS. 19-23 depict an example power semiconductor package 900 according to example embodiments of the present disclosure. FIGS. 19-23 are intended to represent structures for identification and description and is not intended to represent the structures to physical scale. FIG. 19 depicts a top view of the power semiconductor package 900, and FIGS. 20-21 depict a cross-sectional perspective view of the power semiconductor package 900 taken along the line AA′ shown in FIG. 19. The power semiconductor package 900 is similar to the power semiconductor package 700 of FIGS. 15-17. However, the power semiconductor package 900 includes one or more different conductive patterns on different layers of the first carrier submount 710. FIGS. 22-23 depict top views of opposing sides of the first carrier submount 710. More particularly, FIG. 22 depicts a top view of the first surface 705A of the insulating layer 705, and FIG. 23 depicts a top view of the second surface 705B of the insulating layer 705.

As noted above, the power semiconductor package 900 is similar to the power semiconductor package 700 discussed above. For instance, the power semiconductor package 900 includes a first carrier submount 710. The first carrier submount 710 includes one or more conductive patterns (e.g., conductive pattern 712 and conductive pattern 714) disposed on opposing sides of an insulating layer 705. The power semiconductor package 900 includes a second carrier submount 730 (e.g., lead frame). The second carrier submount 730 includes one or more conductive leads (e.g., conductive lead 732) for the power semiconductor package 900.

In some embodiments, such as the example shown in FIG. 21, the power semiconductor package 900 may include the thermally conductive cooling layer 716. More particularly, in the example of FIG. 21, the power semiconductor package 900 includes a second insulating layer 902 disposed between the conductive pattern 714 and the thermally conductive cooling layer 716. The power semiconductor package 900 further includes a third conductive layer (e.g., thermally conductive cooling layer 716) on the second insulating layer 902. Furthermore, as discussed above, the thermally conductive cooling layer 716 may be exposed through the encapsulating portion 750 (e.g., through opening 752).

The power semiconductor package 900 includes a plurality of semiconductor die 720. Like the power semiconductor package 700 discussed above (e.g., FIGS. 15-17), the power semiconductor package 900 does not include any wire bonds to the plurality of semiconductor die 720. Furthermore, each semiconductor die 720 includes a first surface 720A and an opposing second surface 720B. The first surface 720A of each of the semiconductor die 720 is directly coupled to the first carrier submount 710 (e.g., in a flip chip configuration) such that a first contact 722 (e.g., source contact) and a third contact 726 (e.g., gate contact) are directly coupled to the first carrier submount 710. The second surface 720B of each of the semiconductor die 720 is directly coupled to the second carrier submount 730 such that a second contact 724 (e.g., drain contact) is directly coupled to the second carrier submount 730. In this manner, each semiconductor die 720 of the plurality of semiconductor die 720 may be coupled to a common source terminal 760 (via respective first contact 722), to a common drain terminal 770 (via respective second contact 724), and to a common gate terminal 780.

It should be noted that the four semiconductor die 720 depicted in FIGS. 19-23 are arranged in a parallel configuration for purposes of illustration and discussion. The power semiconductor package 900 may include more than four semiconductor die 720 and/or less than four semiconductor die 720 arranged in a parallel configuration and/or a series configuration without deviating from the scope of the present disclosure.

The power semiconductor package 900 includes an encapsulating portion 750. In some embodiments (e.g., FIG. 20), the thermally conductive cooling layer 716 is exposed through an opening 752 in the encapsulating portion. Additionally and/or alternatively, in some embodiments (e.g., FIG. 21), the thermally conductive cooling layer 716 may be covered by the encapsulating portion 750.

As noted above, the first carrier submount 710 of the power semiconductor package 900 may include one or more conductive patterns (e.g., conductive pattern 712, conductive pattern 714) on different layers of the first carrier submount 710. More specifically, the first carrier submount 710 may include a first conductive layer (e.g., conductive pattern 712), a second conductive layer (e.g., conductive pattern 714), and an insulating layer (e.g., insulating layer 705) between the first conductive layer and the second conductive layer. As shown, the first conductive layer (e.g., conductive pattern 712) may be directly coupled to the first contact 722 (e.g., source contact) of each semiconductor die 720 of the plurality of semiconductor die 720. The first conductive layer (e.g., conductive pattern 712) may also be coupled to the second carrier submount 730. Similarly, the second conductive layer (e.g., conductive pattern 714) may be coupled to the third contact 726 (e.g., gate contact) of each semiconductor die 720 of the plurality of semiconductor die 720 through one or more electrically conductive vias. As will be discussed in greater detail below, the first conductive layer (e.g., conductive pattern 712) and the second conductive layer (e.g., conductive pattern 714) may include different conductive patterns. For instance, the first conductive layer (e.g., conductive pattern 712) may include a source pattern, and the second conductive layer (e.g., conductive pattern 714) may include a gate pattern.

FIG. 22 depicts a top view of the first conductive layer of the first carrier submount 710. The first conductive layer may have one or more thermally and/or electrically conductive patterns, such as conductive pattern 712 (e.g., source pattern). The first conductive layer may be copper, silver, gold, titanium, or other suitable conductive material. Furthermore, as noted above, the first conductive layer may be directly coupled to the first contact 722 (e.g., source contact) of each of the plurality of semiconductor die 720. In this way, the first conductive layer of the first carrier submount 710 allows each semiconductor die 720 of the power semiconductor package 900 to be coupled to a common source terminal 760. The first conductive layer may further include a plurality of holes 912. As will be discussed in greater detail below, each of the plurality of holes 912 may correspond to (e.g., align with) a via 922 of the second conductive layer (e.g., conductive pattern 714).

FIG. 23 depicts a top view of the second conductive layer of the first carrier submount 710. The second conductive layer may have one or more thermally and/or electrically conductive patterns, such as conductive pattern 714 (e.g., gate pattern). In this way, the second conductive layer may include a different conductive pattern (e.g., conductive pattern 714) than the first conductive layer (e.g., conductive pattern 712). The second conductive layer may be copper, silver, gold, titanium, or other suitable conductive material. The second conductive layer may include a plurality of vias 922. The plurality of vias 922 may extend through the insulating layer 705 separating the first conductive layer and the second conductive layer. Each via 922 of the plurality of vias 922 may correspond to (e.g., align with) a hole 912 of the plurality of holes 912 in the first conductive layer (e.g., conductive pattern 712) so as to electrically isolate the first conductive layer (e.g., conductive pattern 712) and the second conductive layer (e.g., conductive pattern 714). Furthermore, the second conductive layer (e.g., conductive layer 714) may be coupled to the third contact 726 (e.g., gate contact) of each of the plurality of semiconductor die 720 through a respective via 922 of the plurality of vias 922. In this way, the plurality of vias 922 of the first carrier submount 710 allows each semiconductor die 720 of the power semiconductor package 900 to be coupled to a common gate terminal 780.

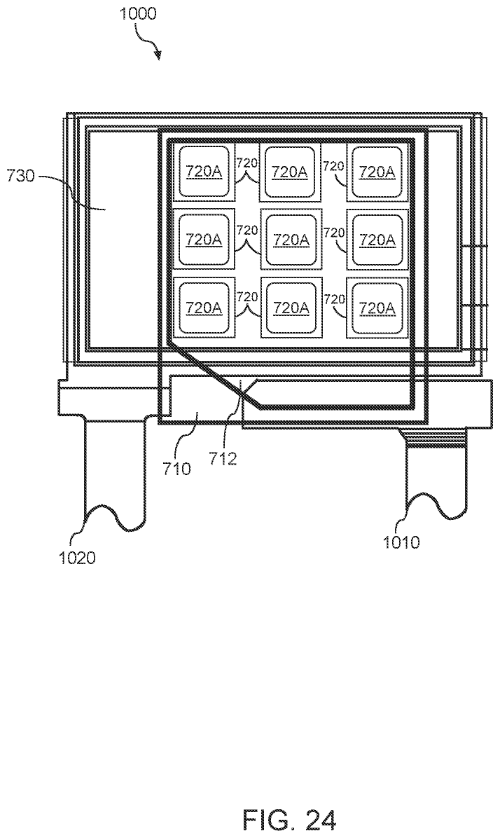

FIG. 24 depicts a power semiconductor package 1000 that is similar to the power semiconductor package 700 of FIGS. 15-17. FIG. 24 is intended to represent structures for identification and description and is not intended to represent the structures to physical scale. The power semiconductor package 1000 includes a first carrier submount 710. The first carrier submount 710 includes one or more conductive patterns (e.g., conductive pattern 712) and a thermally conductive cooling layer 716. The power semiconductor package 1000 includes a second carrier submount 730. The second carrier submount 730 includes one or more conductive leads (e.g., conductive lead 732) for the power semiconductor package 1000. The power semiconductor package 1000 includes a plurality of semiconductor die 720.

In the example of FIG. 24, the plurality of semiconductor die 720 may include a plurality of Schottky diodes, such as one or more silicon carbide-based Schottky diodes. Each semiconductor die 720 includes a first surface 720A and an opposing second surface 720B. The first surface 720A of each of the semiconductor die 720 is directly coupled to the first carrier submount 710 (e.g., in a flip chip configuration) such that a first contact 722 (e.g., an anode contact) is directly coupled to the first carrier submount 710. The second surface 720B of each of the semiconductor die 720 is directly coupled to the second carrier submount 730 such that a second contact 724 (e.g., cathode contact) is directly coupled to the second carrier submount 730. In this manner, each semiconductor die 720 of the plurality of semiconductor die 720 may be coupled to a common anode terminal 1010 (via respective first contact 722) and to a common cathode terminal 1020 (via respective second contact 724).

The power semiconductor package 1000 includes an encapsulating portion 750. In some embodiments, the thermally conductive cooling layer 716 is exposed through an opening 752 in the encapsulating portion. Additionally and/or alternatively, in some embodiments, the thermally conductive cooling layer 716 may be covered by the encapsulating portion 750.

It should be noted that the nine semiconductor die 720 (e.g., Schottky diodes) depicted in FIG. 24 are arranged in a parallel configuration for purposes of illustration and discussion. The power semiconductor package 1000 may include more than nine semiconductor die 720, and/or less than nine semiconductor die 720, arranged in a parallel configuration and/or a series configuration without deviating from the scope of the present disclosure.

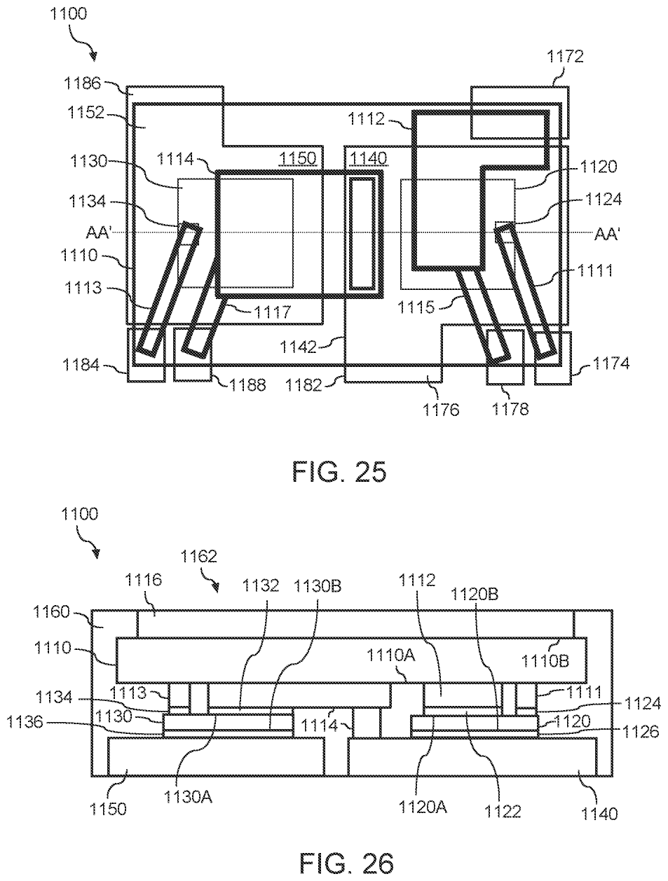

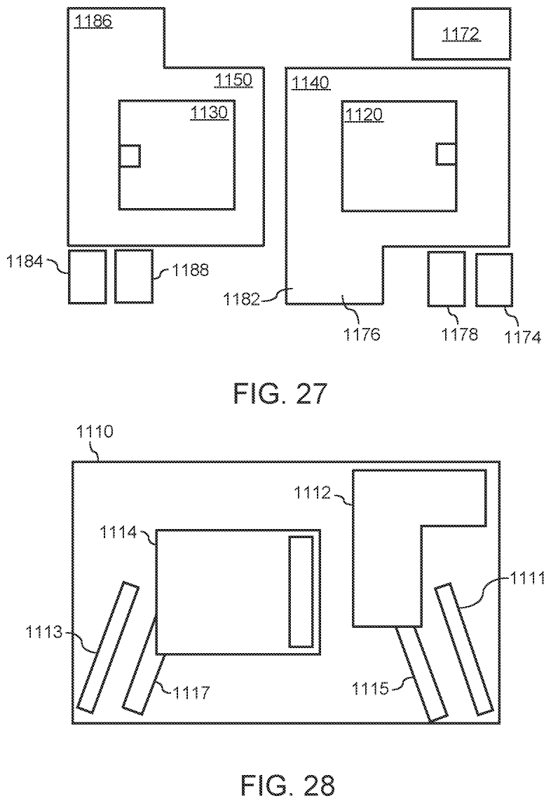

FIGS. 25-28 depict an example power semiconductor package 1100 according to example embodiments of the present disclosure. FIGS. 25-28 are intended to represent structures for identification and description and is not intended to represent the structures to physical scale. FIG. 25 depicts a top view of the power semiconductor package 1100, and FIG. 26 depicts a cross-sectional perspective view of the power semiconductor package 1100 taken along the line AA′ shown in FIG. 25. The power semiconductor package 1100 is similar to the power semiconductor package 700 of FIGS. 15-17 and the power semiconductor package 900 of FIGS. 19-23. However, in contrast to the power semiconductor package 700 and the power semiconductor package 900, the power semiconductor package 1100 includes two semiconductor die (e.g., semiconductor die 1120, semiconductor die 1130) having individual (e.g., separate) source terminals, drain terminals, gate terminals, and kelvin terminals. FIG. 27 depicts a portion of a first lead frame 1140 and a second lead frame 1150 of the power semiconductor package 1100, and FIG. 28 depicts a carrier submount 1110 of the power semiconductor package 1100.

As shown, the power semiconductor package 1100 includes a carrier submount 1110. The carrier submount 1110 may be an active metal brazed (AMB) substrate, a direct bonded copper (DBC) substrate, or other suitable substrate. The carrier submount 1110 may include a dielectric and/or a ceramic substrate, such as alumina, aluminum nitride, silicon nitride, or other suitable dielectric material.

The carrier submount 1110 may have a first surface 1110A and an opposing second surface 1110B. The carrier submount 1110 may have one or more thermally and/or electrically conductive patterns on the first surface 1110A, such as conductive pattern 1111, conductive pattern 1112, conductive pattern 1113, and conductive pattern 1114. The one or more conductive patterns (e.g., conductive patterns 1111, 1112, 1113, 1114) may be copper, silver, gold, titanium, or other suitable conductive material. The carrier submount 1110 may have a thermally conductive cooling layer 1116 (e.g., a copper pattern) on the second surface 1110B. The thermally conductive cooling layer 1116 may be copper, silver, gold, titanium, or other suitable conductive material. Furthermore, although the power semiconductor package 1100 is depicted in FIGS. 25-28 as having one or more conductive patterns on the same layer of the carrier submount 1110, the power semiconductor package 1100 may include one or more conductive patterns on different layers of the carrier submount 1110 (e.g., in a similar manner as described above with reference to FIGS. 19-23) without deviating from the scope of the present disclosure.

The power semiconductor package 1100 includes a plurality of semiconductor die, such as first semiconductor die 1120 and second semiconductor die 1130. As will be discussed in greater detail below, the power semiconductor package 1100 does not include any wire bonds to the first semiconductor die 1120. Likewise, the power semiconductor package 1100 does not include any wire bonds to the second semiconductor die 1130. In some embodiments, the first semiconductor die 1120 and the second semiconductor die 1130 may be directly coupled to the carrier submount 1110 in, e.g., a flip chip configuration. Furthermore, as shown, in some embodiments, the plurality of semiconductor die (e.g., semiconductor die 1120, semiconductor die 1130) may be arranged in a half-bridge configuration. However, those having ordinary skill in the art, using the disclosures provided herein, will appreciate that the plurality of semiconductor die (e.g., semiconductor die 1120, semiconductor die 1130) may be arranged in any suitable configuration without deviating from the scope of the present disclosure.

The first semiconductor die 1120 and the second semiconductor die 1130 may each include one or more semiconductor devices, such as one or more transistors, diodes, thyristors, or other devices. In some embodiments, the first semiconductor die 1120 and the second semiconductor die 1130 may each be a wide bandgap semiconductor die. For instance, the first semiconductor die 1120 and the second semiconductor die 1130 may include silicon carbide. More specifically, the first semiconductor die 1120 and the second semiconductor die 1130 may each include a silicon carbide-based MOSFET. Additionally and/or alternatively, the first semiconductor die 1120 and the second semiconductor die 1130 may each include a silicon carbide-based Schottky diode.

The power semiconductor package 1100 further includes a plurality of lead frames (e.g., copper lead frames), such as first lead frame 1140 and second lead frame 1150. The plurality of lead frames (e.g., first lead frame 1140, second lead frame 1150) each include one or more conductive leads configured to facilitate connection of the power semiconductor package 1100 to an external component(s), such as one or more circuits. For instance, as shown in FIG. 26, the first lead frame 1140 may include a conductive lead 1142, and the second lead frame 1150 may include a conductive lead 1152.

The first semiconductor die 1120 may include a first surface 1120A and an opposing second surface 1120B. The first surface 1120A may be directly coupled to the carrier submount 1110, and the second surface 1120B may be directly coupled the first lead frame 1140. Furthermore, the first semiconductor die 1120 may include a source contact 1122 and a gate contact 1124 on the first surface 1120A. The first semiconductor die 1120 may further include a drain contact 1126 on a second surface 1120B of the first semiconductor die 1120. More particularly, the source contact 1122 may be coupled to at least one of the one or more conductive patterns of the carrier submount 1110, such as conductive pattern 1112, without the use of wire bonds. The gate contact 1124 may be coupled to at least one of the one or more conductive patterns of the carrier submount 1110, such as conductive pattern 1111, without the use of wire bonds. The drain contact 1126 may be coupled to at least one of the one or more conductive leads of the first lead frame 1140, such as conductive lead 1142, without the use of wire bonds.

The second semiconductor die 1130 may include a first surface 1130A and an opposing second surface 1130B. The first surface 1130A may be directly coupled to the carrier submount 1110, and the second surface 1130B may be directly coupled the second lead frame 1150. Furthermore, the second semiconductor die 1130 may include a source contact 1132 and a gate contact 1134 on the first surface 1130A. The second semiconductor die 1130 may further include a drain contact 1136 on a second surface 1130B of the second semiconductor die 1130. More particularly, the source contact 1132 may be coupled to at least one of the one or more conductive patterns of the carrier submount 1110, such as conductive pattern 1114, without the use of wire bonds. The source contact 1132 may also be coupled to at least one of the one or more conductive leads of the first lead frame 1140, such as conductive lead 1142, without the use of wire bonds. The gate contact 1134 may be coupled to at least one of the one or more conductive patterns of the carrier submount 1110, such as conductive pattern 1113, without the use of wire bonds. The drain contact 1136 may be coupled to at least one of the one or more conductive leads of the second lead frame 1150, such as conductive lead 1152, without the use of wire bonds.

In some embodiments, the first semiconductor die 1120 may include a kelvin contact 1128 on the first surface 1120A of the first semiconductor die 1120, and the second semiconductor die 1130 may include a kelvin contact 1138 on the first surface 1130A of the second semiconductor die 1130. The kelvin contact 1128 of the first semiconductor die 1120 may be coupled to at least one of the one or more conductive patterns of the carrier submount 1110, such as conductive pattern 1115, without the use of wire bonds. The kelvin contact 1138 of the second semiconductor die 1130 may be coupled to at least one of the one or more conductive patterns of the carrier submount 1110, such as conductive pattern 1117, without the use of wire bonds.

In some embodiments, the power semiconductor package 1100 may include an encapsulating portion 1160. The encapsulating portion 1160 may form a housing for the power semiconductor package 1100. The encapsulating portion 1160 may be formed by a molding process such that the encapsulating portion 1160 is provided at least partially around the carrier submount 1110, the first semiconductor die 1120, the second semiconductor die 1130, the first lead frame 1140, and the second lead frame 1150. The material of the encapsulating portion 1160 may electrically isolate the components within the power semiconductor package 1100 from each other. The material of the encapsulating portion 1160 may be a dielectric material. Example materials for the encapsulating portion 1160 may include an epoxy material or an epoxy mold compound (EMC).

In some embodiments, such as that shown in FIG. 26, the thermally conductive cooling layer 1116 on the carrier submount 1110 may be exposed through the encapsulating portion 1160. More particularly, as shown, the thermally conductive cooling layer 1116 may be exposed through an opening 1162 in the encapsulating portion 1160. As such, the thermally conductive cooling layer 1116 may provide a third thermally conductive path for cooling of the plurality of semiconductor die (e.g., first semiconductor die 1120, second semiconductor die 1130) in the power semiconductor package 1100. More particularly, the first thermally conductive path may be provided through the first lead frame 1140 and the one or more conductive leads, such as conductive lead 1142. The second thermally conductive path may be provided through the second lead frame 1150 and the one or more conductive leads, such as conductive lead 1152. The third thermally conductive path may be provided through opening 1162 in the encapsulating portion 1160. The thermally conductive cooling layer 1116 may be coupled to a heat sink and/or may provide a thermally conductive path to an ambient environment of the power semiconductor package 1100.

In other embodiments, similar to the power semiconductor die 700 depicted in FIG. 17, the thermally conductive cooling layer 1116 on the carrier submount 1110 may be covered by the encapsulating portion 1160, rather than being exposed through an opening (e.g., opening 1162) of the encapsulating portion 1160 as depicted in FIG. 26. In such embodiments, the first thermally conductive path may be provided through the first lead frame 1140 and the one or more conductive leads, such as conductive lead 1142, and the second thermally conductive path may be provided through the second lead frame 1150 and the one or more conductive leads, such as conductive lead 1152.

Referring again to FIGS. 25-28, as noted above, the first semiconductor die 1120 and the second semiconductor die 1130 may be coupled to different source terminals of the power semiconductor package 1100. For instance, the source contact 1122 of the first semiconductor die 1120 may be coupled to source terminal 1172, and the source contact 1132 of the second semiconductor die 1130 may be coupled to source terminal 1182. The first semiconductor die 1120 and the second semiconductor die 1130 may be coupled to different gate terminals of the power semiconductor package 1100. For instance, the gate contact 1124 of the first semiconductor die 1120 may be coupled to gate terminal 1174, and the gate contact 1134 of the second semiconductor die 1130 may be coupled to gate terminal 1184. The first semiconductor die 1120 and the second semiconductor die 1130 may be coupled to different drain terminals of the power semiconductor package 1100. For instance, the drain contact 1126 of the first semiconductor die 1120 may be coupled to drain terminal 1176, and the drain contact 1136 of the second semiconductor die 1130 may be coupled to drain terminal 1186. Furthermore, in embodiments where the first semiconductor die 1120 and the second semiconductor die 1130 are arranged in a half-bridge configuration, the drain terminal 1176 of the first semiconductor die 1170 may be coupled to the source terminal 1182 of the second semiconductor die 1130 via, e.g., the first lead frame 1140.

Furthermore, in embodiments where the first semiconductor die 1120 includes kelvin contact 1128 and the second semiconductor die 1130 includes kelvin contact 1138, the first semiconductor die 1120 and the second semiconductor die 1130 may be coupled to different kelvin terminals. More particularly, the kelvin contact 1128 of the first semiconductor die 1120 may be coupled to kelvin contact 1178, and kelvin contact 1138 of the second semiconductor die 1130 may be coupled to kelvin terminal 1188.

Example aspects of the present disclosure are provided in the following paragraphs, the examples of which may be combined to form various different embodiments of the present disclosure.

One example embodiment of the present disclosure is directed to a power semiconductor package. The power semiconductor package includes a first carrier submount, a second carrier submount, and a plurality of semiconductor die. Each semiconductor die of the plurality of semiconductor die has a first surface and an opposing second surface. Furthermore, for each semiconductor die of the plurality of semiconductor die, the first surface is directly coupled to the first carrier submount, and the second surface is directly coupled to the second carrier submount.

In some examples, each semiconductor die of the plurality of semiconductor die comprises a first contact on the first surface and a second contact on the second surface.

In some examples, the first carrier submount comprises one or more conductive patterns. Furthermore, for each semiconductor die of the plurality of semiconductor die, the first contact is directly coupled to at least one of the one or more conductive patterns of the first carrier submount, and the second contact is directly coupled to the second carrier submount.

In some examples, each semiconductor die further comprises a third contact on the first surface.

In some examples, for each semiconductor die of the plurality of semiconductor die, the third contact is directly coupled to at least one of the one or more conductive patterns of the first carrier submount, and the first contact and the third contact are coupled to different conductive patterns of the first carrier submount.

In some examples, for each semiconductor die of the plurality of semiconductor die, the first contact is a source contact, the second contact is a drain contact, and the third contact is at least one of a gate contact or a kelvin contact.

In some examples, each semiconductor die of the plurality of semiconductor die are coupled to a common source terminal.

In some examples, the second carrier submount comprises a plurality of conductive leads, and each drain contact of the plurality of semiconductor die is coupled to a different conductive lead of the plurality of conductive leads.

In some examples, each semiconductor die of the plurality of semiconductor die are coupled to a common drain terminal.

In some examples, each source contact of the plurality of semiconductor die is coupled to a different conductive pattern of the one or more conductive patterns.

In some examples, each semiconductor die of the plurality of semiconductor die are coupled to a common gate terminal.

In some examples, the power semiconductor package further includes an encapsulating portion, the encapsulating portion comprising a dielectric material.

In some examples, the plurality of semiconductor die are directly coupled to the first carrier submount in a flip chip configuration.

In some examples, the first carrier submount comprises a direct bonded copper (DBC) substrate or an active metal brazed (AMB) substrate.

In some examples, the second carrier submount comprises a lead frame for the power semiconductor package.

In some examples, the first carrier submount comprises a first conductive layer, a second conductive layer, and an insulating layer between the first conductive layer and the second conductive layer.

In some examples, the first conductive layer comprises a source pattern and a gate pattern.

In some examples, the first conductive layer and the second conductive layer comprise different conductive patterns.

In some examples, the power semiconductor package further includes a plurality of vias extending through the insulating layer connecting the second conductive layer to the plurality of semiconductor die.

In some examples, the second conductive layer is a thermally conductive cooling layer.

In some examples, the thermally conductive cooling layer is exposed through an encapsulating portion of the power semiconductor package.

In some examples, the thermally conductive cooling layer is covered by an encapsulating portion of the power semiconductor package.

In some examples, the first carrier submount comprises a second insulating layer on the second conductive layer and a third conductive layer on the second insulating layer.

In some examples, the third conductive cooling layer is a thermally conductive cooling layer.

In some examples, the plurality of semiconductor die comprises a plurality of wide bandgap semiconductor die.

In some examples, the plurality of wide bandgap semiconductor die comprise silicon carbide.

In some examples, the power semiconductor package does not include any wire bonds to the plurality of semiconductor die.

In some examples, each semiconductor die of the plurality of semiconductor die comprises a silicon carbide-based MOSFET.

In some examples, the silicon carbide-based MOSFETs of the plurality of semiconductor die are arranged in parallel.

In some examples, each semiconductor die of the plurality of semiconductor die comprises a silicon carbide-based Schottky diode.

In some examples, the silicon carbide-based Schottky diodes of the plurality of semiconductor die are arranged in parallel.

In some examples, a number of semiconductor die in the plurality of semiconductor die is in a range of two semiconductor die to nine semiconductor die.

Another example embodiment of the present disclosure is directed to a power semiconductor package. The power semiconductor package includes a first carrier submount, a second carrier submount, and a plurality of semiconductor die. The first carrier submount has a first conductive layer and a second conductive layer. Each semiconductor die of the plurality of semiconductor die includes a first surface and an opposing second surface, a source contact and a gate contact on the first surface, and a drain contact on the second surface. Furthermore, for each semiconductor die of the plurality of semiconductor die, the first surface is directly coupled to the first carrier submount such that the source contact is directly coupled to the first conductive layer of the first carrier submount and the gate contact is directly coupled to the second conductive layer of the first carrier submount. Even further, for each semiconductor die of the plurality of semiconductor die, the second surface is directly coupled to the second carrier submount.

In some examples, for each semiconductor die of the plurality of semiconductor die, the gate contact is coupled to the second conductive layer of the first carrier submount through a via.

In some examples, the power semiconductor package does not include any wire bonds to the plurality of semiconductor die.

In some examples, the first carrier submount comprises a direct bonded copper (DBC) substrate or an active metal brazed (AMB) substrate.

In some examples, the second carrier submount comprises a lead frame for the power semiconductor package.

In some examples, the first layer of the first carrier submount is coupled to the plurality of semiconductor die and to the lead frame.

In some examples, each semiconductor die of the plurality of semiconductor die are coupled to a common source terminal.

In some examples, the second carrier submount comprises a plurality of conductive leads, and each drain contact of the plurality of semiconductor die is coupled to a different conductive lead of the plurality of conductive leads.

In some examples, each semiconductor die of the plurality of semiconductor die are coupled to a common drain terminal.

In some examples, the first carrier submount comprises a plurality of conductive patterns, and each source contact of the plurality of semiconductor die is coupled to a different conductive pattern of the plurality of conductive patterns.

In some examples, each semiconductor die of the plurality of semiconductor die are coupled to a common gate terminal.

In some examples, each semiconductor die of the plurality of semiconductor die further comprises a kelvin contact on the first surface.

In some examples, each semiconductor die of the plurality of semiconductor die are coupled to a common kelvin terminal.

In some examples, the power semiconductor package further includes an encapsulating portion.

In some examples, the first carrier submount comprises a thermally conductive cooling layer exposed through the encapsulating portion.

In some examples, the first carrier submount comprises a thermally conductive cooling layer that is covered by the encapsulating portion.

In some examples, the plurality of semiconductor die are directly coupled to the first carrier submount in a flip chip configuration.

In some examples, the plurality of semiconductor die comprises a plurality of wide bandgap semiconductor die.

In some examples, the plurality of wide bandgap semiconductor die are silicon carbide-based semiconductor die.

In some examples, the plurality of semiconductor die comprises a plurality of silicon carbide-based MOSFETs.

In some examples, the plurality of silicon carbide-based MOSFETs are arranged in parallel.

In some examples, the plurality of semiconductor die comprises a plurality of silicon carbide-based Schottky diodes.

In some examples, the plurality of silicon carbide-based Schottky diodes are arranged in parallel.

In some examples, a number of semiconductor die in the plurality of semiconductor die is in a range of two semiconductor die to nine semiconductor die.

Another example embodiment of the present disclosure is directed to a power semiconductor package. The power semiconductor package includes a carrier submount comprising one or more conductive patterns, a first lead frame comprising one or more conductive leads, a second lead frame comprising one or more conductive leads, a first semiconductor die having a first surface directly coupled to the carrier submount and an opposing second surface directly coupled to the first lead frame, and a second semiconductor die having a first surface directly coupled to the carrier submount and an opposing second surface directly coupled to the second lead frame. The first semiconductor die further includes a source contact on the first surface coupled to at least one of the one or more conductive patterns of the carrier submount, a gate contact on the first surface coupled to at least one of the one or more conductive patterns of the carrier submount, and a drain contact on the second surface coupled to at least one of the one or more conductive leads of the first lead frame. The second semiconductor die further includes a source contact on the first surface coupled to at least one of the one or more conductive patterns of the carrier submount and to at least one of the one or more conductive leads of the first lead frame, a gate contact on the first surface coupled to at least one of the one or more conductive patterns of the carrier submount, and a drain contact on the second surface coupled to at least one of the one or more conductive leads of the second lead frame.

In some examples, the carrier submount comprises a thermally conductive cooling layer exposed through an encapsulating portion of the power semiconductor package.

In some examples, the carrier submount comprises a thermally conductive cooling layer covered by an encapsulating portion of the power semiconductor package.

In some examples, the source contact of the first semiconductor die and the source contact of the second semiconductor die are coupled to different source terminals of the power semiconductor package.

In some examples, the gate contact of the first semiconductor die and the gate contact of the second semiconductor die are coupled to different gate terminals of the power semiconductor package.

In some examples, the drain contact of the first semiconductor die and the drain contact of the second semiconductor die are coupled to different drain terminals of the power semiconductor package.

In some examples, the first semiconductor die further comprises a kelvin contact on the first surface, the kelvin contact coupled to at least one of the one or more conductive patterns of the carrier submount. Furthermore, the second semiconductor die further comprises a kelvin contact on the first surface, the kelvin contact coupled to at least one of the one or more conductive patterns of the carrier submount.

In some examples, the kelvin contact of the first semiconductor die and the kelvin contact of the second semiconductor die are coupled to different kelvin terminals of the power semiconductor package.

In some examples, the power semiconductor package does not include any wire bonds to the first semiconductor die.

In some examples, the power semiconductor package does not include any wire bonds to the second semiconductor die.

In some examples, the carrier submount comprises a direct bonded copper (DBC) substrate or an active metal brazed (AMB) substrate.

In some examples, the first semiconductor die and the second semiconductor die are directly coupled to the carrier submount in a flip chip configuration.

In some examples, the first semiconductor die comprises a first wide bandgap semiconductor die, and the second semiconductor die comprises a second wide bandgap semiconductor die.

In some examples, the first wide bandgap semiconductor die and the second wide bandgap semiconductor die are silicon carbide-based semiconductor die.

In some examples, the first wide bandgap semiconductor is a silicon carbide-based MOSFET, and the second wide bandgap semiconductor is a silicon carbide-based MOSFET.

In some examples, the first wide bandgap semiconductor is a silicon carbide-based Schottky diode, and the second wide bandgap semiconductor is a silicon carbide-based Schottky diode.

In some examples, the first semiconductor die and the second semiconductor die are arranged in a half-bridge configuration.

Another example embodiment of the present disclosure is directed to a power semiconductor package. The power semiconductor package includes a first carrier submount, a second carrier submount, and a semiconductor die. The first carrier submount includes a first conductive layer, a second conductive layer, and an insulating layer between the first conductive layer and the second conductive layer. The semiconductor die includes a first surface and an opposing second surface. Furthermore, the first conductive layer and the second conductive layer comprise different conductive patterns.

In some examples, the first conductive layer comprises a source pattern, and the second conductive layer comprises a gate pattern.

In some examples, the first carrier submount further comprises a via extending through the insulating layer connecting the second conductive layer to the semiconductor die.

In some examples, the semiconductor die comprises a source contact on the first surface and a drain contact on the second surface.

In some examples, the semiconductor die further comprises a gate contact on the first surface.

In some examples, the power semiconductor package further includes an encapsulating portion, the encapsulating portion comprising a dielectric material.

In some examples, the semiconductor die is directly coupled to the first carrier submount in a flip chip configuration.

In some examples, the first carrier submount comprises a direct bonded copper (DBC) substrate or an active metal brazed (AMB) substrate.

In some examples, the semiconductor die comprises a wide bandgap semiconductor die.

In some examples, the wide bandgap semiconductor die comprises silicon carbide.

In some examples, the wide bandgap semiconductor die comprises a silicon carbide-based MOSFET.

In some examples, the wide bandgap semiconductor die comprises a silicon carbide-based Schottky diode.

In some examples, the power semiconductor package does not include any wire bonds to the semiconductor die.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor package, comprising:
a first carrier submount;
a second carrier submount; and
a plurality of semiconductor die, each semiconductor die of the plurality of semiconductor die having a first surface and an opposing second surface;
wherein, for each semiconductor die of the plurality of semiconductor die:
the first surface is directly coupled to the first carrier submount; and
the second surface is directly coupled to the second carrier submount.

2. (canceled)

3. The power semiconductor package of claim 1, wherein:
each semiconductor die of the plurality of semiconductor die comprises a first contact on the first surface and a second contact on the second surface:
the first carrier submount comprises one or more conductive patterns; and
for each semiconductor die of the plurality of semiconductor die:
the first contact is directly coupled to at least one of the one or more conductive patterns of the first carrier submount; and
the second contact is directly coupled to the second carrier submount.

4. The power semiconductor package of claim 3, wherein each semiconductor die further comprises a third contact on the first surface, and wherein, for each semiconductor die of the plurality of semiconductor die:
the third contact is directly coupled to at least one of the one or more conductive patterns of the first carrier submount; and
the first contact and the third contact are coupled to different conductive patterns of the first carrier submount.

5. (canceled)

6. The power semiconductor package of claim 4, wherein, for each semiconductor die of the plurality of semiconductor die:
the first contact is a source contact;
the second contact is a drain contact; and
the third contact is at least one of a gate contact or a kelvin contact.

7. The power semiconductor package of claim 6, wherein each semiconductor die of the plurality of semiconductor die are coupled to a common source terminal, the second carrier submount comprises a plurality of conductive leads, and each drain contact of the plurality of semiconductor die is coupled to a different conductive lead of the plurality of conductive leads.

8. (canceled)

9. The power semiconductor package of claim 6, wherein each semiconductor die of the plurality of semiconductor die are coupled to a common drain terminal, each source contact of the plurality of semiconductor die is coupled to a different conductive pattern of the one or more conductive patterns.

10. (canceled)

11. The power semiconductor package of claim 6, wherein each semiconductor die of the plurality of semiconductor die are coupled to a common gate terminal.

12-15. (canceled)

16. The power semiconductor package of claim 1, wherein the first carrier submount comprises:
a first conductive layer;
a second conductive layer; and
an insulating layer between the first conductive layer and the second conductive layer.

17. The power semiconductor package of claim 16, wherein the first conductive layer comprises a source pattern and a gate pattern, and the first conductive layer and the second conductive layer comprise different conductive patterns.

18. (canceled)

19. The power semiconductor package of claim 16, wherein:
the first conductive layer comprises a source pattern;
the second conductive layer comprises a gate pattern; and
the power semiconductor further comprises a plurality of vias extending through the insulating layer connecting the second conductive layer to the plurality of semiconductor die.

20-25. (canceled)

26. The power semiconductor package of claim 1, wherein the plurality of semiconductor die comprises a plurality of wide bandgap semiconductor die, the plurality of wide bandgap semiconductor die comprising silicon carbide.

27. (canceled)

28. The power semiconductor package of claim 1, wherein the power semiconductor package does not include any wire bonds to the plurality of semiconductor die.

29. The power semiconductor package of claim 1, wherein each semiconductor die of the plurality of semiconductor die comprises a silicon carbide-based MOSFET.

30. (canceled)

31. The power semiconductor package of claim 1, wherein each semiconductor die of the plurality of semiconductor die comprises a silicon carbide-based Schottky diode.

32-57. (canceled)

58. A power semiconductor package, comprising:
a carrier submount comprising one or more conductive patterns;
a first lead frame comprising one or more conductive leads;
a second lead frame comprising one or more conductive leads;
a first semiconductor die having a first surface directly coupled to the carrier submount and an opposing second surface directly coupled to the first lead frame, the first semiconductor die further comprising:
a source contact on the first surface coupled to at least one of the one or more conductive patterns of the carrier submount;
a gate contact on the first surface coupled to at least one of the one or more conductive patterns of the carrier submount; and
a drain contact on the second surface coupled to at least one of the one or more conductive leads of the first lead frame; and
a second semiconductor die having a first surface directly coupled to the carrier submount and an opposing second surface directly coupled to the second lead frame, the second semiconductor die further comprising:
a source contact on the first surface coupled to at least one of the one or more conductive patterns of the carrier submount and to at least one of the one or more conductive leads of the first lead frame;
a gate contact on the first surface coupled to at least one of the one or more conductive patterns of the carrier submount; and
a drain contact on the second surface coupled to at least one of the one or more conductive leads of the second lead frame.

59-74. (canceled)

75. A power semiconductor package, comprising:
a first carrier submount, the first carrier submount comprising:
a first conductive layer;
a second conductive layer; and
an insulating layer between the first conductive layer and the second conductive layer;
a second carrier submount; and
a semiconductor die, the semiconductor die having a first surface and an opposing second surface,
wherein the first conductive layer and the second conductive layer comprise different conductive patterns.

76. The power semiconductor package of claim 75, wherein:
the first conductive layer comprises a source pattern; and
the second conductive layer comprises a gate pattern.

77. The power semiconductor package of claim 76, wherein the first carrier submount further comprises a via extending through the insulating layer connecting the second conductive layer to the semiconductor die.

78. The power semiconductor package of claim 77, wherein the semiconductor die comprises a source contact on the first surface and a drain contact on the second surface.

79. The power semiconductor package of claim 78, wherein the semiconductor die further comprises a gate contact on the first surface.

80-87. (canceled)
